(19) United States
(12) Patent Application Publication
(10) Pub. No.: US 2014/0061609 A1
(43) Pub. Date: Mar. 6, 2014

(54) NOVEL COMPOUNDS FOR ORGANIC ELECTRONIC MATERIAL AND ORGANIC ELECTROLUMINESCENT DEVICE USING THE SAME

(71) Applicants: Nam Kyun Kim, Yongin-si (KR); Seok-Keun Yoon, Suwon-si (KR); Jin Hee Kim, Yongin-si (KR); Hyo Jung Lee, Hwaseong-si (KR); Mi Ja Lee, Hwaseong-si (KR); Hee Choon Ahn, Suwon-si (KR); Doo-Hyeon Moon, Hwaseong-si (KR); Jung-Eun Yang, Suwon-si (KR); Hee Sook Kim, Suwon-si (KR); Soo-Jin Hwang, Seoul (KR); Young Jun Cho, Bundang-gu (KR); Kyung Joo Lee, Mapo-gu (KR); Hyuck Joo Kwon, Gangnam-gu (KR); Bong Ok Kim, Gangnam-gu (KR)

(72) Inventors: Nam Kyun Kim, Yongin-si (KR); Seok-Keun Yoon, Suwon-si (KR); Jin Hee Kim, Yongin-si (KR); Hyo Jung Lee, Hwaseong-si (KR); Mi Ja Lee, Hwaseong-si (KR); Hee Choon Ahn, Suwon-si (KR); Doo-Hyeon Moon, Hwaseong-si (KR); Jung-Eun Yang, Suwon-si (KR); Hee Sook Kim, Suwon-si (KR); Soo-Jin Hwang, Seoul (KR); Young Jun Cho, Bundang-gu (KR); Kyung Joo Lee, Mapo-gu (KR); Hyuck Joo Kwon, Gangnam-gu (KR); Bong Ok Kim, Gangnam-gu (KR)

(21) Appl. No.: 13/879,402

(22) PCT Filed: Oct. 13, 2011
(86) PCT No.: PCT/KR2011/007612

§ 371 Date: Nov. 18, 2013

(30) Foreign Application Priority Data
Oct. 13, 2010 (KR) 10-2010-0099589
Oct. 10, 2011 (KR) 10-2011-0102831

(51) Int. Cl. H01L 51/00; H01L 51/50

(52) U.S. Cl. CPC H01L 51/0072; H01L 51/0071; H01L 51/0073; H01L 51/0074; H01L 51/504
USPC 257/40; 544/292; 544/283

(57) ABSTRACT

Provided are novel compounds in accordance with Formula I for an organic electronic material and an organic electroluminescent device using same. The compound for an organic electronic material disclosed herein exhibits high electron transport efficiency and thus prevents crystallization upon manufacturing a device, and also facilitates the formation of a layer, thus improving current properties of the device. Thereby, OLED devices having improved power efficiency as well as reduced operating voltage can be manufactured.

### FIELD OF THE INVENTION

The present invention relates to novel compounds for an organic electronic material and an organic electroluminescent device including the same.

### BACKGROUND OF THE INVENTION

Among display devices, electroluminescence (EL) devices, which are self-emissive display devices, are advantageous in that they provide a wide viewing angle, superior contrast and a fast response rate. In 1987, Eastman Kodak first developed an organic EL device using a low-molecular-weight aromatic diamine and aluminum complex as a substance for forming an electroluminescent layer [Appl. Phys. Lett. 51, 913, 1987].

Organic EL devices emit light using luminescence (phosphorescence or fluorescence) upon inactivation of excitons which result from electron-hole pairs formed by injecting charges into an organic layer formed between an electron injection electrode (cathode) and a hole injection electrode (anode). Organic EL devices can emit polarized light at a luminance of 100˜10,000 cd/m² with a voltage of about 10 V, and simply adopt a fluorescent material, thereby emitting light in the blue to red spectral range. Such a device may be formed on a flexible transparent substrate such as a plastic, and may also operate at a lower voltage, namely 10 V or less, compared to that of a plasma display panel or an inorganic EL display, and may consume comparatively less power and exhibit superior color.

The most important factor in determining the performance including the luminous efficiency, life, etc., of an organic EL device is the electroluminescent material, and some requirements of the electroluminescent material include a high fluorescent quantum yield in a solid phase, high mobility of electrons and holes, slow decomposition upon vacuum deposition, and formation of a uniform and stable thin film.

The organic electroluminescent materials are broadly classified into high-molecular-weight materials and low-molecular-weight materials, and the low-molecular-weight materials include a metal complex compound and a pure organic electroluminescent material without a metal in terms of molecular structure. Such an electroluminescent material is known to be a chelate complex such as a tris(8-quinolinolato)aluminum complex or the like, a coumarin derivative, a tetraphenylbutadiene derivative, a bisstyrylarylene derivative, an oxadiazole derivative, etc., which have been reported to be able to emit visible light ranging from blue to red.

In order to achieve a full-color OLED display, RGB three electroluminescent materials have to be used. The development of RGB electroluminescent materials having high efficiency and long life is important to improve the total properties of the organic EL device. The electroluminescent material includes a host material and a dopant material for purposes of functionality. Typically, a device that has very superior electroluminescent properties is known to have a structure in which a host is doped with a dopant to form an electroluminescent layer. Recently, the development of an organic EL device having high efficiency and long life is being urgently called for. Particularly, taking into consideration the electroluminescent properties required of medium to large OLED panels, the development of materials very superior to conventional electroluminescent materials is urgent, and hence, the development of a host material is regarded as very important. As such, a host material which functions as the solvent in a solid phase and plays a role in transferring energy should be of high purity and must have a molecular weight appropriate to enabling vacuum deposition. Also, the glass transition temperature and heat decomposition temperature should be high to ensure thermal stability, and high electrochemical stability is required to attain a long life, and the formation of an amorphous thin film should become simple, and the force of adhesion to materials of other adjacent layers must be good but interlayer migration should not occur.

In the case where an organic EL device is manufactured using a doping technique, the rate at which energy is transferred from a host molecule in an excited state to a dopant is not 100%, and the host material as well as the dopant may emit light. In particular, in the case of a red-emitting electroluminescent device, a host material emits light in a wavelength range that is more clearly visible than does a dopant, and thus color purity is deteriorated due to unclear light emission of the host material. In practice, EL life and durability should be improved.

At present, CBP is most widely known as a host material for a phosphorescent material. High-efficiency OLEDs using a hole blocking layer comprising BCP, BAlq, etc. are reported. High-performance OLEDs using BAlq derivatives as a host were reported by Pioneer (Japan) and others.

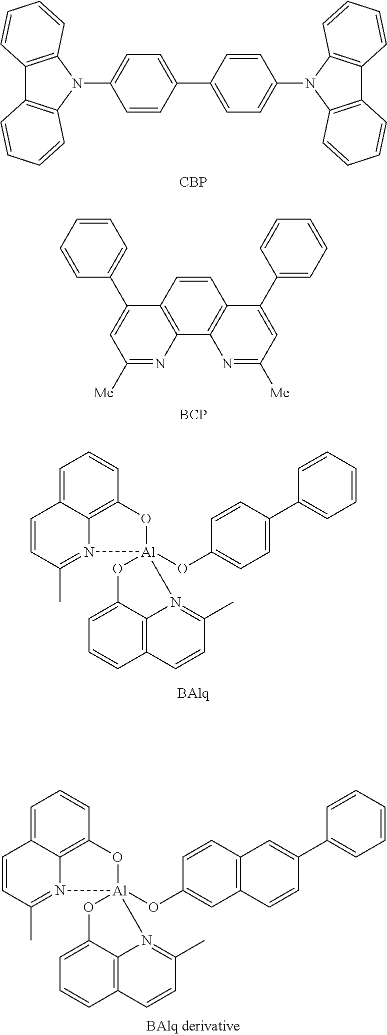

Although these conventional materials provide good electroluminescent properties, they are disadvantageous in that degradation may occur during the high-temperature vapor deposition process in a vacuum because of the low glass transition temperature and poor thermal stability. Because the power efficiency of an OLED is given by (π/voltage)×current efficiency, power efficiency is inversely proportional to the voltage, and should thus be high in order to reduce the power consumption of an OLED. Actually, OLEDs using phosphorescent materials provide much higher current efficiency (cd/A) than do those using fluorescent materials. However, when existing materials such as BAlq, CBP or the like are used as the host of the phosphorescent material, there is no significant advantage in power efficiency (Im/W) over the OLEDs using fluorescent materials because of the high operating voltage. Furthermore, the life of an OLED device is not satisfactory, and therefore the development of a more stable host material having higher performance is required.

Meanwhile, International Publication No. WO 2006/049013 discloses a compound for organic electroluminescent element employing a fused bicyclic group as a frame. However, the document does not disclose the structure that all of heterocycloalkyl or cycloalkyl fused with an aromatic ring, and a carbazole group fused with the heterocycloalkyl or the cycloalkyl fused with an aromatic ring are combined as well as a frame of a fused bicyclic group containing nitrogen is adopted.

### Technical Problem

Therefore, the present invention has been made keeping in mind the problems occurring in the related art and an object of the present invention is to provide a compound for an organic electronic material, which has a backbone so that it can achieve better luminous efficiency and device life with appropriate color coordinates compared to conventional materials.

Another object of the present invention is to provide an organic electroluminescent device having high efficiency and a long life using the compound for an organic electronic material as an electroluminescent material.

### Technical Solution

Provided are a compound for an organic electronic material represented by Chemical Formula 1 below, and an organic electroluminescent device including the same. With superior luminous efficiency and excellent life, the compound for an organic electronic material according to the present invention may be used to manufacture an OLED device having very superior operating life and consuming less power due to improved power efficiency.

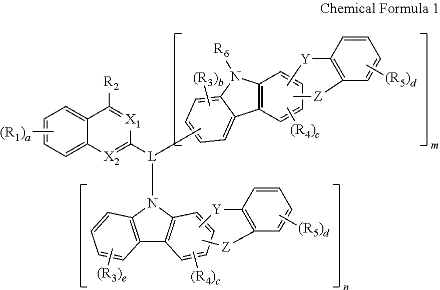

In Chemical Formula 1, L represents a single bond, (C6-C30)arylene or (C2-C30)heteroarylene;

X₁ and X₂ independently represent CR′ or N, in which both X₁ and X₂ are not CR′;

one of Y and Z is essentially a single bond, and the other is —C(R₇)(R₈)—, —N(R₉)—, —O—, —S— or —Si(R₁₀)(R₁₁)—;

R′, R₁ through R₆ independently represent hydrogen, deuterium, (C1-C30)alkyl, halo(C1-C30)alkyl, halogen, cyano, (C3-C30)cycloalkyl, 5- to 7-membered heterocycloalkyl, (C2-C30)alkenyl, (C2-C30)alkynyl, (C6-C30)aryl, (C2-C30)heteroaryl, (C6-C30)ar(C1-C30)alkyl, N-carbazolyl, —NR₁₂R₁₃, —SiR₁₄R₁₅R₁₆, —SR₁₇, —OR₁₈, nitro or hydroxyl;

R₇ through R₁₁ and R₁₂ through R₁₈ independently represent hydrogen, deuterium, halogen, (C1-C30)alkyl, (C6-C30)aryl or (C2-C30)heteroaryl, and R₇ and R₈ may be linked via (C3-C30)alkylene or (C3-C30)alkenylene with or without a fused ring to form a spiro ring;

the arylene and heteroarylene of L and L₁ and the alkyl, cycloalkyl, heterocycloalkyl, alkenyl, alkynyl, aryl and heteroaryl of R′, R₁ through R₆ may be independently further substituted with one or more selected from the group consisting of deuterium, (C1-C30)alkyl, halo(C1-C30)alkyl, halogen, cyano, (C3-C30)cycloalkyl, 5- to 7-membered heterocycloalkyl, (C2-C30)alkenyl, (C2-C30)alkynyl, (C6-C30)aryl, (C₁-C30)alkoxy, (C6-C30)aryloxy, (C2-C30)heteroaryl, (C6-C30)aryl-subsititued (C2-C30)heteroaryl, (C6-C30)ar(C1-C30)alkyl, (C1-C30)alkyl(C6-C30)aryl, (C6-C30)arylthio, mono or di(C1-C30)alkylamino, mono or di(C6-C30)arylamino, (C1-C30)alkyl(C6-C30)arylamino, di(C6-C30)arylboronyl, di(C1-C30)alkylboronyl, (C1-C30)alkyl(C6-C30)arylboronyl, tri(C1-C30)alkylsilyl, di(C1-C30)alkyl(C6-C30)arylsilyl, (C1-C30)alkyldi(C6-C30)arylsilyl, tri(C6-C30)arylsilyl, N-carbazolyl, carboxyl, nitro and hydroxyl;

a, d and e independently represent an integer of 1 to 4, and when they are integers of 2 or larger, each substituent may be identical or different from each other;

b represents an integer of 1 to 3, and when they are integers of 2 or larger, each substituent may be identical or different from each other;

c represents an integer of 1 to 2, and when they are integers of 2 or larger, each substituent may be identical or different from each other;

m and n independently represent an integer of 0 or 1, and m+n equals to 1;

the heteroarylene, heterocycloalkyl and heteroaryl include one or more heteroatoms selected from the group consisting of B, N, O, S, P(═O), Si and P.

As described herein, “alkyl”, “alkoxy” and other substituents containing the “alkyl” moiety include both linear and branched species, and “cycloalkyl” includes monocyclic hydrocarbon as well as polycyclic hydrocarbons such as substituted or unsubstituted adamantyl or substituted or unsubstituted (C7-C30)bicycloalkyls. As described herein, the term “aryl” means an organic radical derived from an aromatic hydrocarbon by the removal of one hydrogen atom, and includes a 4- to 7-membered, particularly 5- or 6-membered, single ring or fused ring, and even further includes a structure where a plurality of aryls are linked by single bonds. Specific examples thereof include phenyl, naphthyl, biphenyl, terphenyl, anthryl, indenyl, fluorenyl, phenanthryl, triphenylenyl, pyrenyl, perylenyl, chrysenyl, naphthacenyl, fluoranthenyl, or the like, but are not limited thereto. The naphthyl includes 1-naphthyl and 2-naphthyl, and the anthryl includes 1-anthryl, 2-anthryl and 9-anthryl, and the fluorenyl includes 1-fluorenyl, 2-fluorenyl, 3-fluorenyl, 4-fluorenyl and 9-fluorenyl. The “heteroaryl” described herein means an aryl group containing 1 to 4 heteroatom(s) selected from the group consisting of B, N, O, S, P(═O), Si and P as aromatic ring backbone atom(s) and the remaining aromatic ring backbone atom is carbon. It may be a 5- or 6-membered monocyclic heteroaryl, polycyclic heteroaryl or polycyclic heteroaryl fused with one or more benzene rings, and may be partially saturated. In the present invention, “heteroaryl” includes a structure where one or more heteroaryls are linked by single bonds. The heteroaryl includes a divalent heteroaryl group wherein the heteroatom(s) in the ring may be oxidized or quaternized to form, for example, N-oxide or a quaternary salt. Specific examples thereof include monocyclic heteroaryl such as furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, furazanyl, pyridyl, pyrazinyl, pyrimidinyl, pyridazinyl, or the like, polycyclic heteroaryl such as benzofuranyl, benzothiophenyl, isobenzofuranyl, benzoimidazolyl, benzothiazolyl, benzoisothiazolyl, benzoisoxazolyl, benzoxazolyl, isoindolyl, indolyl, indazolyl, benzothiadiazolyl, quinolyl, isoquinolyl, cinnolinyl, quinazolinyl, quinoxalinyl, carbazolyl, phenanthridinyl, benzodioxolyl, or the like, N-oxide thereof (e.g., pyridyl N-oxide, quinolyl N-oxide), quaternary salt thereof, and the like, but are not limited thereto.

As described herein, the term “(C1-C30)alkyl” includes (C1-C20)alkyl or (C1-C10)alkyl, and the term “(C6-C30)aryl” includes (C6-C20)aryl or (C6-C12)aryl. The term “(C2-C30)heteroaryl” includes (C2-C20)heteroaryl or (C2-C12)heteroaryl, and the term “(C3-C30)cycloalkyl” includes (C3-C20)cycloalkyl or (C3-C7)cycloalkyl. The term, “(C2-C30)alkenyl or alkynyl” includes (C2-C20)alkenyl or alkynyl, or (C2-C10)alkenyl or alkynyl.

The compound for an organic electronic material according to the present invention includes a compound for an organic electronic material represented by Chemical Formula 2 or 3 below.

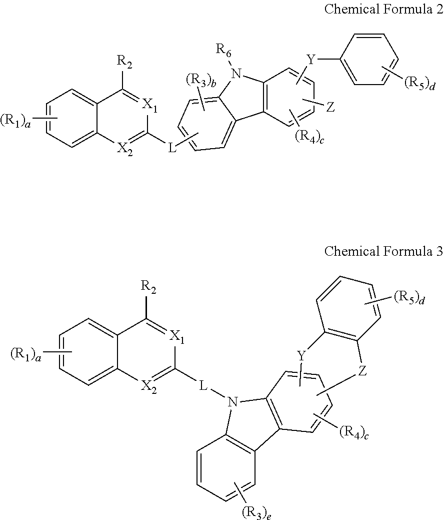

In Chemical Formula 2 or 3, R₁ through R₆, X₁, X₂, L, Y, Z, a, b, c, d and e are the same as defined in Chemical Formula 1.

The compound for an organic electronic material according to the present invention includes a compound for an organic electronic material represented by Chemical Formula 4 below.

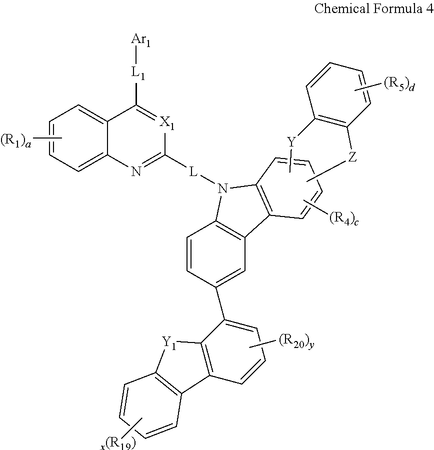

In Chemical Formula 4, R₁, R₄, R₅, L, X₁, Y, Z, a, c and d are the same as defined in Chemical Formula 1; R₁₉ and R₂₀ independently represent hydrogen, deuterium, (C1-C30)alkyl, halo(C1-C30)alkyl, halogen, cyano, (C3-C30)cycloalkyl, 5- or 7-membered heterocycloalkyl, (C2-C30)alkenyl, (C2-C30)alkynyl, (C6-C30)aryl, (C2-C30)heteroaryl, (C6-C30)ar(C1-C30)alkyl, —NR₁₂R₁₃, —SiR₁₄R₁₅R₁₆, —SR₁₇, —OR₁₈, nitro or hydroxyl; R₁₂ through R₁₈ are the same as defined in Chemical Formula 1; L₁ represents a single bond, (C2-C30)heteroarylene or (C6-C30)arylene; Ar₁ represents hydrogen, deuterium, (C2-C30)heteroaryl, (C6-C30)aryl or (C1-C30)alkyl; Y₁ represents —O—, —S—, —CR₂₁R₂₂— or —NR₂₃—, R₂₁ through R₂₃ independently represent hydrogen, deuterium, halogen, (C1-C30)alkyl, (C6-C30)aryl or (C2-C30)heteroaryl; x and y independently represent an integer of 1 to 4; arylene, heteroarylene of the L₁, alkyl, cycloalkyl, heterocycloalkyl, alkenyl, alkynyl, aryl, heteroaryl, aralkyl of R₁₉ and R₂₀, and heteroaryl, aryl or alkyl of Ar₁, alkyl, aryl or heteroaryl of R₂₁ through R₂₂ may be independently further substituted with one or more selected from the group consisting of deuterium, (C1-C30)alkyl, halo(C1-C30)alkyl, halogen, cyano, (C3-C30)cycloalkyl, 5- or 7-membered heterocycloalkyl, (C2-C30)alkenyl, (C2-C30)alkynyl, (C6-C30)aryl, (C1-C30)alkoxy, (C6-C30)aryloxy, (C2-C30)heteroaryl, (C6-C30)aryl-substituted (C3-C30)heteroaryl, (C6-C30)ar(C1-C30)alkyl, (C1-C30)alkyl(C6-C30)aryl, (C6-C30)arylthio, mono or di(C1-C30)alkylamino, mono or di(C6-C30)arylamino, (C1-C30)alkyl(C6-C30)arylamino, di(C6-C30)arylboronyl, di(C1-C30)alkylboronyl, (C1-C30)alkyl(C6-C30)arylboronyl, tri(C1-C30)alkylsilyl, di(C1-C30)alkyl(C6-C30)arylsilyl, (C1-C30)alkyldi(C6-C30)arylsilyl, tri(C6-C30)arylsilyl, N-carbazolyl, carboxyl, nitro and hydroxyl.

To be specific, the

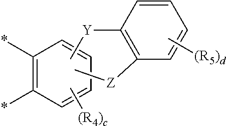

is selected from following structures but not limited thereto.

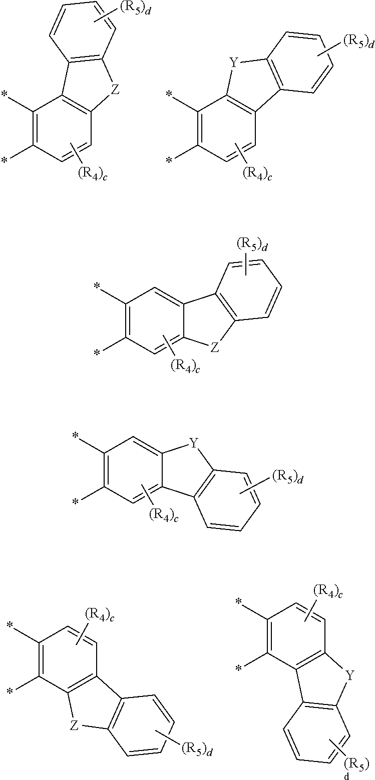

wherein, the Y, Z, R₄, R₅, c and d are the same as defined in Chemical Formula 1.

To be specific, L represents a single bond or (C6-C30)arylene; X₁ and X₂ independently represent CH or N, wherein both X₁ and X₂ are not CH; one of Y and Z is essentially a single bond, and the other is —C(R₇)(R₈)—, —N(R₉)—, —O— or —S—; and R₁ through R₆ independently represent hydrogen, deuterium, (C1-C30)alkyl, halo(C1-C30)alkyl (C6-C30)aryl, (C2-C30)heteroaryl or N-carbazolyl; R₇ through R₉ independently represent (C1-C30)alkyl or (C6-C30)aryl, and R₇ and R₈ may be linked via (C3-C7)alkylene to form a spiro ring; arylene of the L, alkyl, aryl, or heteroaryl of R₁ through R₆ and alkyl or aryl of R₇ through R₉ may be independently substituted with one or more selected from the group consisting of deuterium, (C1-C30)alkyl, halo(C1-C30)alkyl, halogen, (C6-C30)aryl, (C2-C30)heteroaryl and N-carbazolyl.

Also, in Chemical Formula 3, the L₁ represents a single bond, (C2-C30)heteroarylene or (C6-C30)arylene; Ar₁ represents hydrogen, deuterium, (C2-C30)heteroaryl, (C6-C30)aryl or (C1-C30)alkyl; Y₁ represents —O—, —S—, —CR₂₁R₂₂— or —NR₂₃—; R₂₁ through R₂₃ independently represent hydrogen, deuterium, (C1-C30)alkyl, (C6-C30)aryl or (C2-C30)heteroaryl; R₁₉ and R₂₀ independently represent hydrogen, deuterium, halogen, (C1-C30)alkyl, (C6-C30)aryl or (C2-C30)heteroaryl; L represents a single bond or (C6-C30)arylene; X₂ represents CH or N; at least one of Y and Z represents a single bond, and the other represents —C(R₇)(R₈)—, —N(R₉)—, —O— or —S—; R₁, R₄ and R₅ independently represent hydrogen, deuterium, (C1-C30)alkyl, halo(C1-C30)alkyl, (C6-C30)aryl, (C2-C30)heteroaryl or N-carbazolyl; R₇ through R₉ independently represent (C1-C30)alkyl or (C6-C30)aryl, and R₇ and R₈ may be linked via (C3-C7)alkylene to form a spiro ring; arylene of the L, heteroarylene or arylene of L₁, alkyl, aryl, heteroaryl of R₁, R₄, R₅, Ar₁, R₁₉, R₂₀, and R₂₁ through R₂₃, and alkyl or aryl of R₇ through R₉ may be independently further substituted with one or more selected from the group consisting of deuterium, (C1-C30)alkyl, halo(C1-C30)alkyl, halogen, (C6-C30)aryl, (C2-C30)heteroaryl and N-carbazolyl.

More specifically, the compound for an organic electronic material according to the present invention may be exemplified by the compounds of FIGS. 1 to 10, which are not intended to limit the present invention.

The compound for an organic electronic material according to the present invention may be prepared as shown in Schemes 1 and 2 below, but is not limited thereto, and may also be prepared using known methods of organic synthesis.

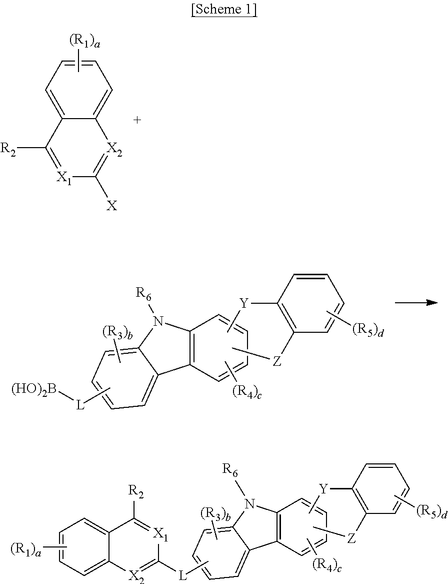

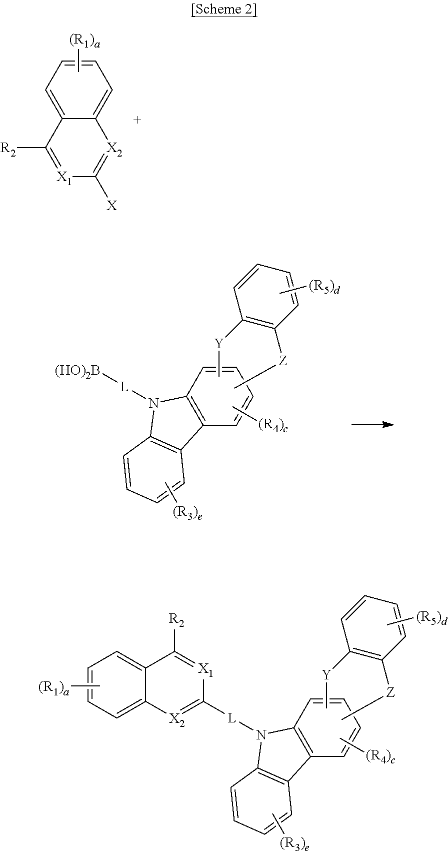

In Schemes 1 and 2, R₁ through R₆, X₁, X₂, L, Y, Z, a, b, c, d and e are the same as defined in Chemical Formula 1; and X represents a halogen.

Provided is an organic electroluminescent device, which comprises a first electrode; a second electrode; and one or more organic layers interposed between the first electrode and the second electrode, wherein the organic layer comprises one or more compounds for an organic electronic material of Chemical Formula 1. The organic layer includes an electroluminescent layer, and the compound for an organic electronic material of Chemical Formula 1 is used as a host material in the electroluminescent layer.

In the electroluminescent layer, when the compound for an organic electronic material of Chemical Formula 1 is used as a host, one or more phosphorescent dopants may be included. The phosphorescent dopant applied to the organic electroluminescent device of the present invention is not specifically limited but the metal included in the phosphorescent dopant applied to the organic electroluminescent device of the present invention may be selected from Ir, Pt and Cu, which are not intended to limit the present invention. The phosphorescent dopant compound is specifically exemplified in FIGS. 11 and 12 but is not limited thereto.

The organic electroluminescent device according to the present invention includes the compound for an organic electronic material of Chemical Formula 1, and may further include one or more compounds selected from the group consisting of arylamine compounds and styrylarylamine compounds. Specific examples of the arylamine compounds or the styrylarylamine compounds are illustrated in Korean Patent Publication Nos. 10-2010-0064712, or 10-2010-0048447, but are not limited thereto.

In the organic electroluminescent device according to the present invention, the organic layer may further comprise one or more metals selected from the group consisting of organic metals of Group 1, Group 2, 4^{th} period and 5^{th} period transition metals, lanthanide metals and d-transition elements or complex compounds, in addition to the compound for an organic electronic material of Chemical Formula 1. The organic layer may comprise an electroluminescent layer and a charge generating layer.

Further, the organic layer may include one or more organic electroluminescent layers including compounds emitting red, green and blue light at the same time, in addition to the above compound for an organic electronic material, in order to embody a white-emitting organic electroluminescent device. The compounds emitting red, green and blue light may be exemplified by the compounds described in Korean Patent Publication Nos. 10-2010-0064712, or 10-2010-0048447, but are not limited thereto.

In the organic electroluminescent device according to the present invention, a layer (hereinafter referred to as “surface layer”) selected from a chalcogenide layer, a metal halide layer and a metal oxide layer may be placed on the inner surface of one or both electrodes among the pair of electrodes. Specifically, a metal chalcogenide (including the oxide) layer of silicon and aluminum may be placed on the anode surface of the electroluminescent medium layer, and a metal halide layer or a metal oxide layer may be placed on the cathode surface of the electroluminescent medium layer. Operation stability may be attained therefrom. The chalcogenide may be, for example, SiOₓ (1≦x≦2), AlOₓ (1≦x≦1.5), SiON, SiAlON, etc. The metal halide may be, for example, LiF, Mg F₂, CaF₂, a rare earth metal fluoride, etc. The metal oxide may be, for example, Cs₂O, Li₂O, MgO, SrO, BaO, CaO, etc.

In the organic electroluminescent device according to the present invention, it is also preferable to arrange on at least one surface of the pair of electrodes thus manufactured a mixed region of an electron transport compound and a reductive dopant, or a mixed region of a hole transport compound and an oxidative dopant. In that case, because the electron transport compound is reduced to an anion, injection and transport of electrons from the mixed region to an electroluminescent medium are facilitated. In addition, because the hole transport compound is oxidized to a cation, injection and transport of holes from the mixed region to an electroluminescent medium are facilitated. Preferable oxidative dopants include a variety of Lewis acids and acceptor compounds. Preferable reductive dopants include alkali metals, alkali metal compounds, alkaline earth metals, rare-earth metals, and mixtures thereof. Further, a white-emitting organic electroluminescent device having two or more electroluminescent layers may be manufactured by employing a reductive dopant layer as a charge generating layer.

### Advantageous Effects

According to the present invention, compounds for an organic electronic material can be used to manufacture OLED devices having improved power efficiency as well as reduced operating voltage while exhibiting good luminous efficiency.

### DESCRIPTION OF THE DRAWINGS

The above and other objects, features and advantages of the present invention will become apparent from the following description of preferred embodiments given in conjunction with the accompanying drawings, in which:

FIGS. 1 to 10 show compounds for an organic electronic material according to specific exemplary embodiments.

FIGS. 11 and 12 show a phosphorescent dopant compound according to an exemplary embodiment.

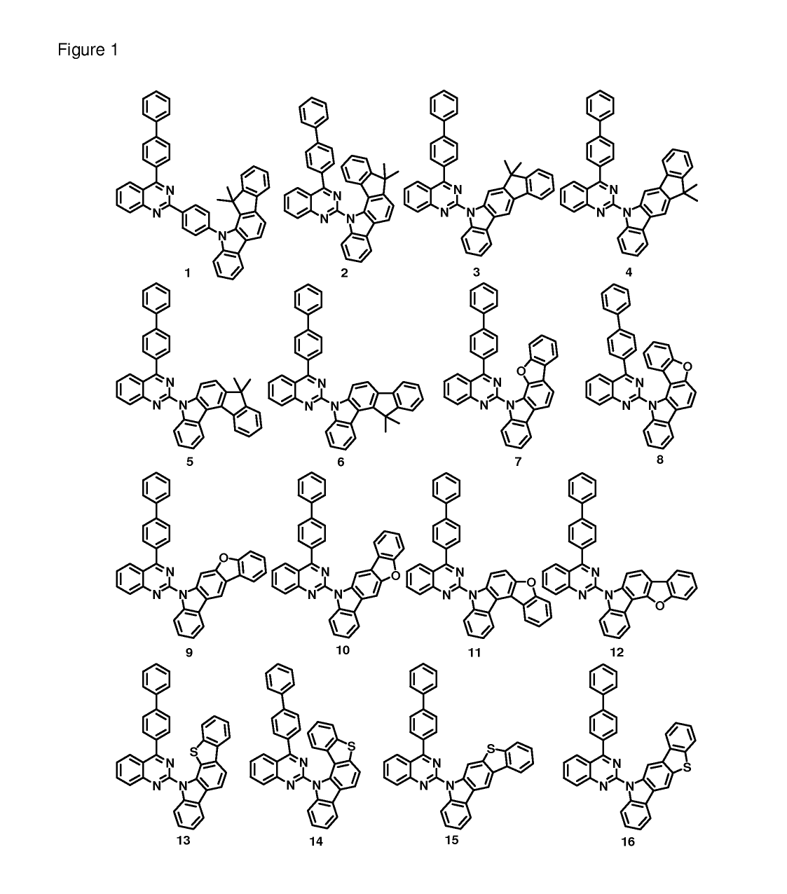

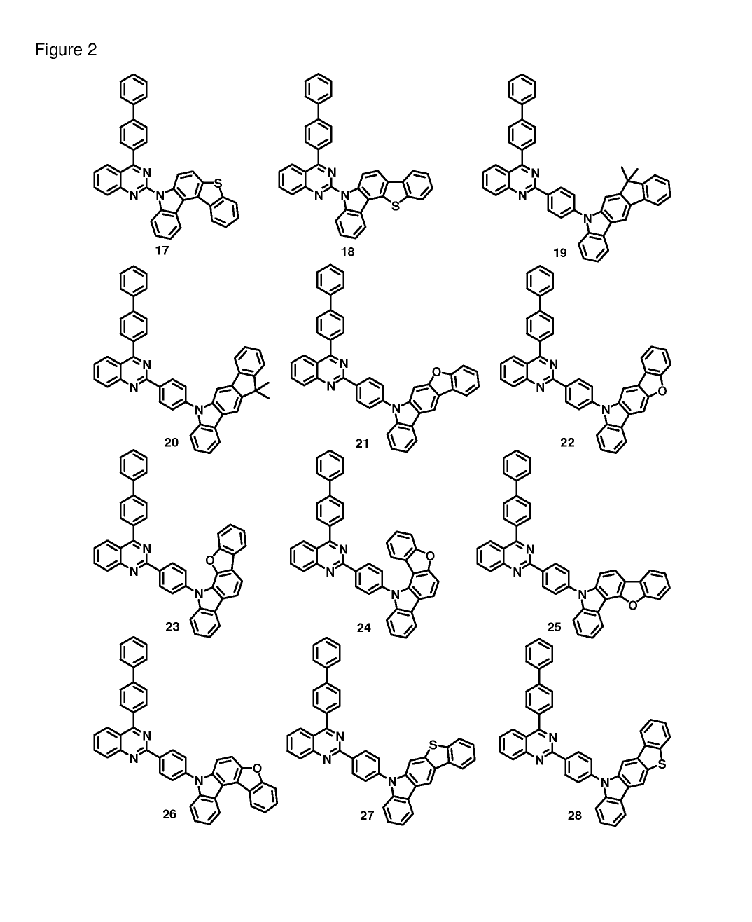

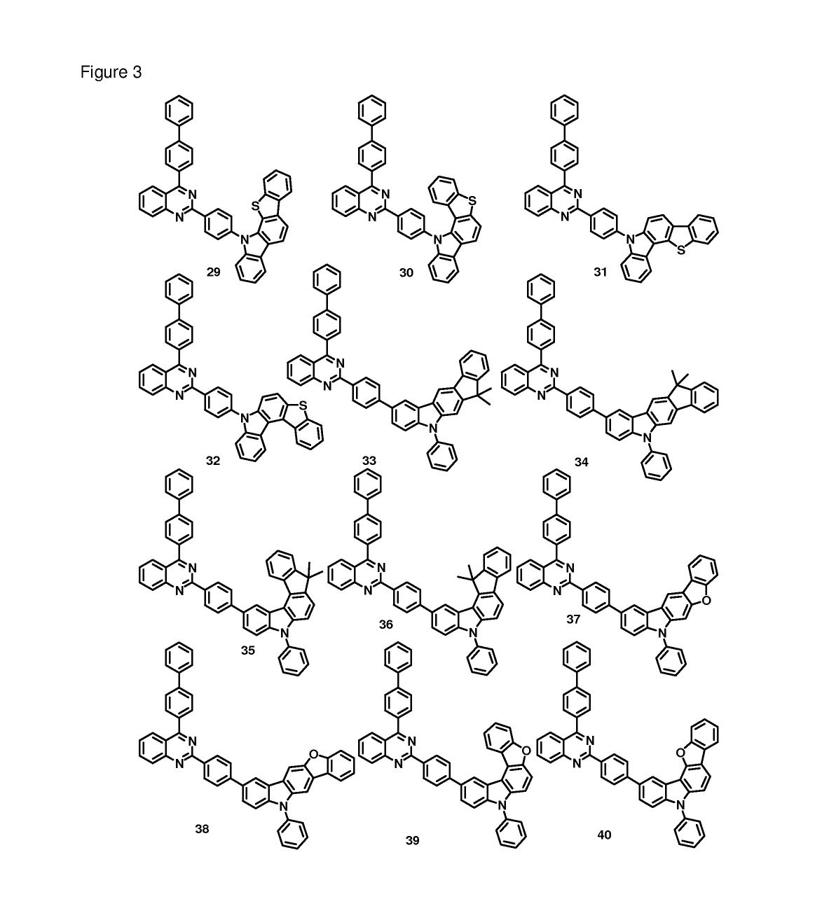

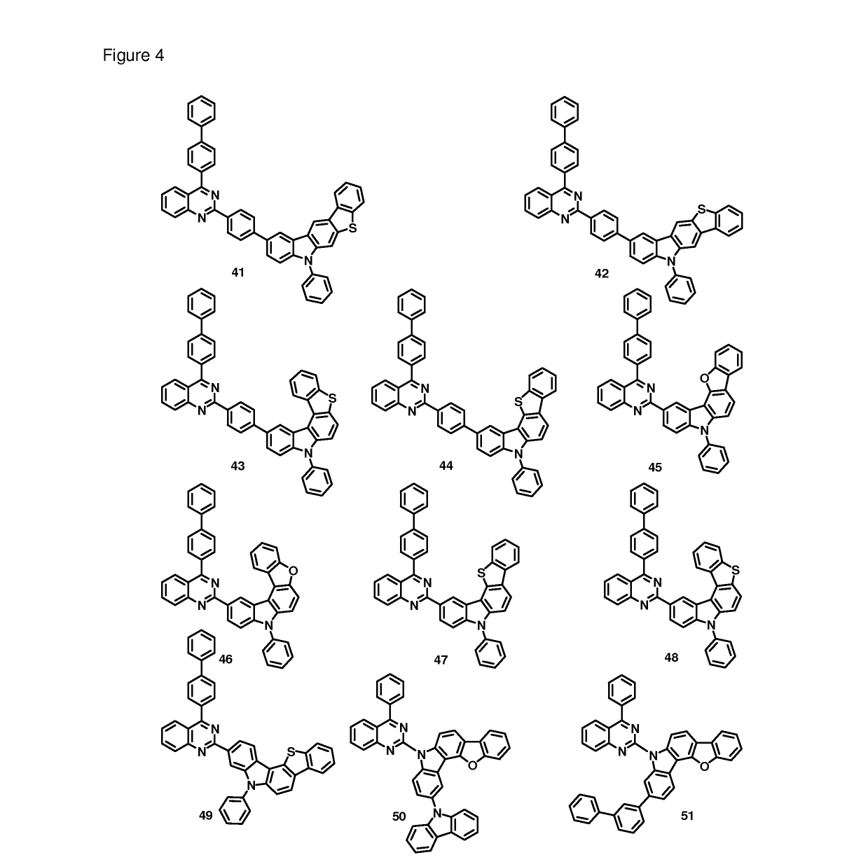

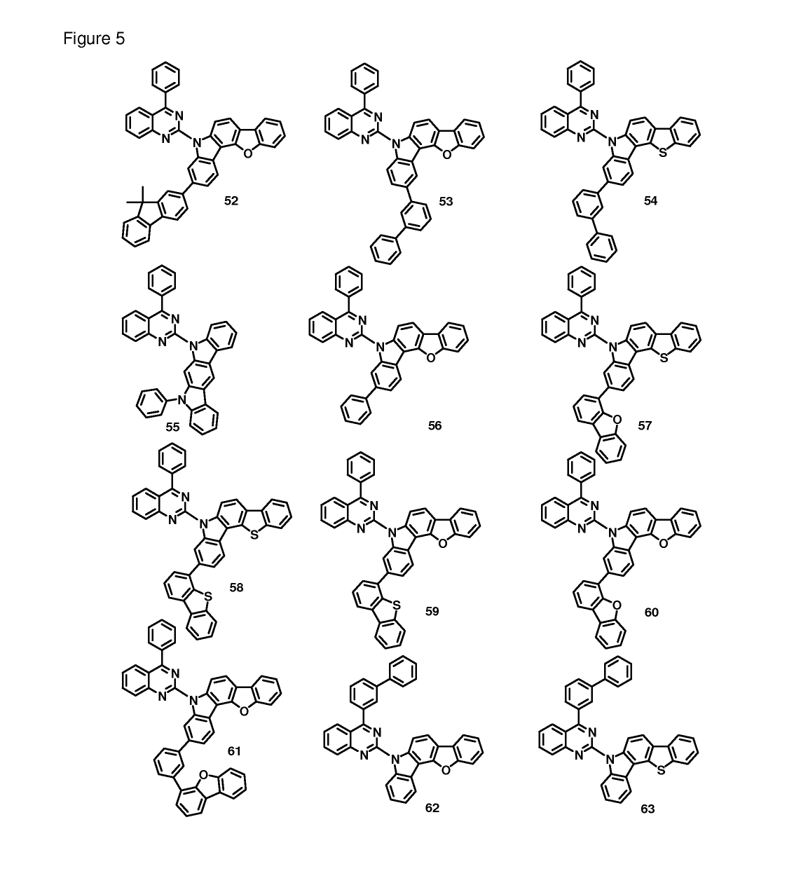

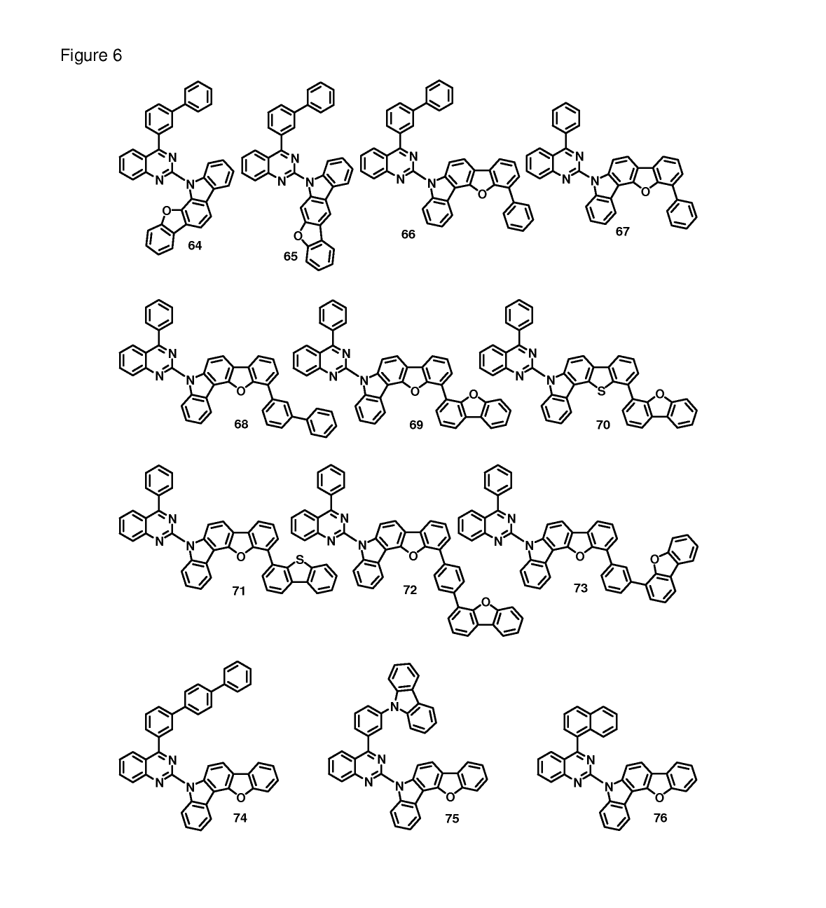

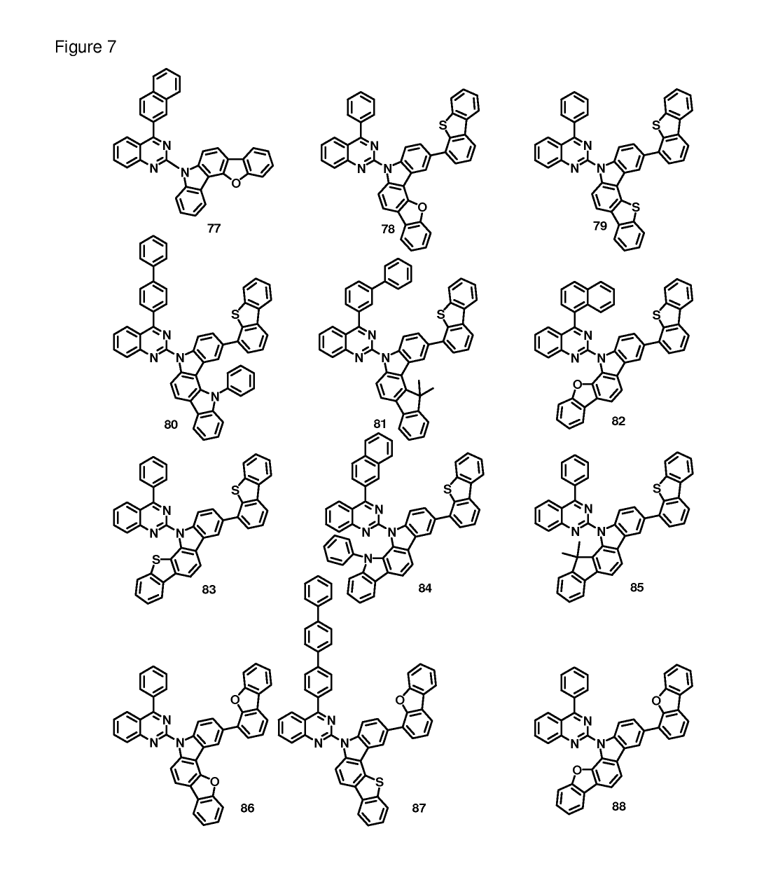

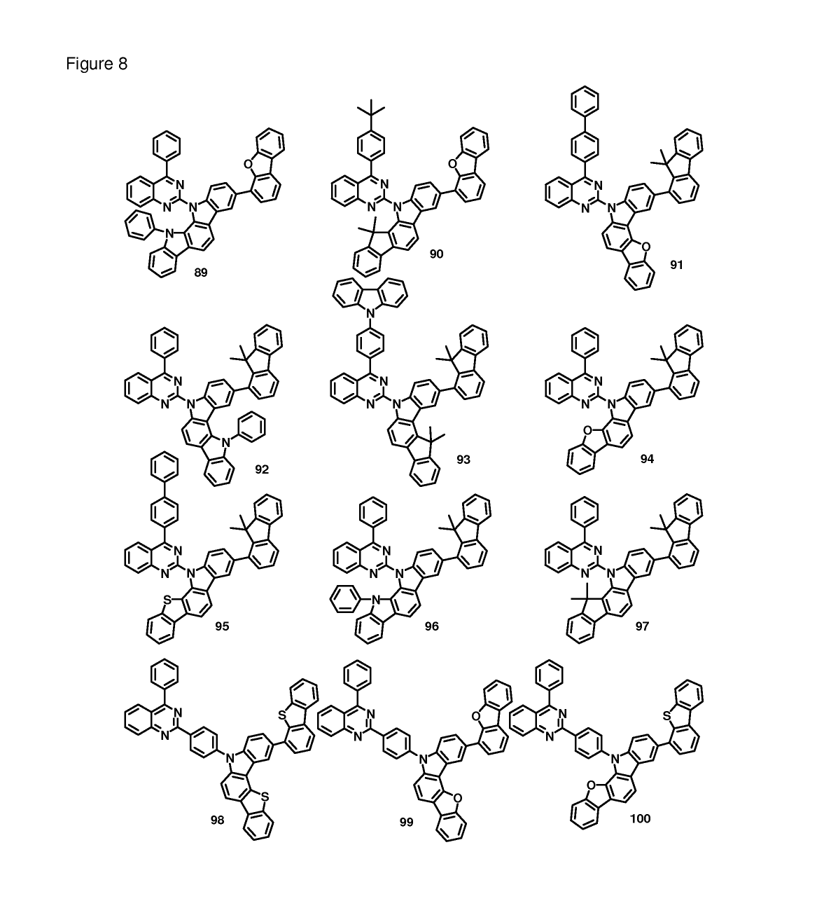

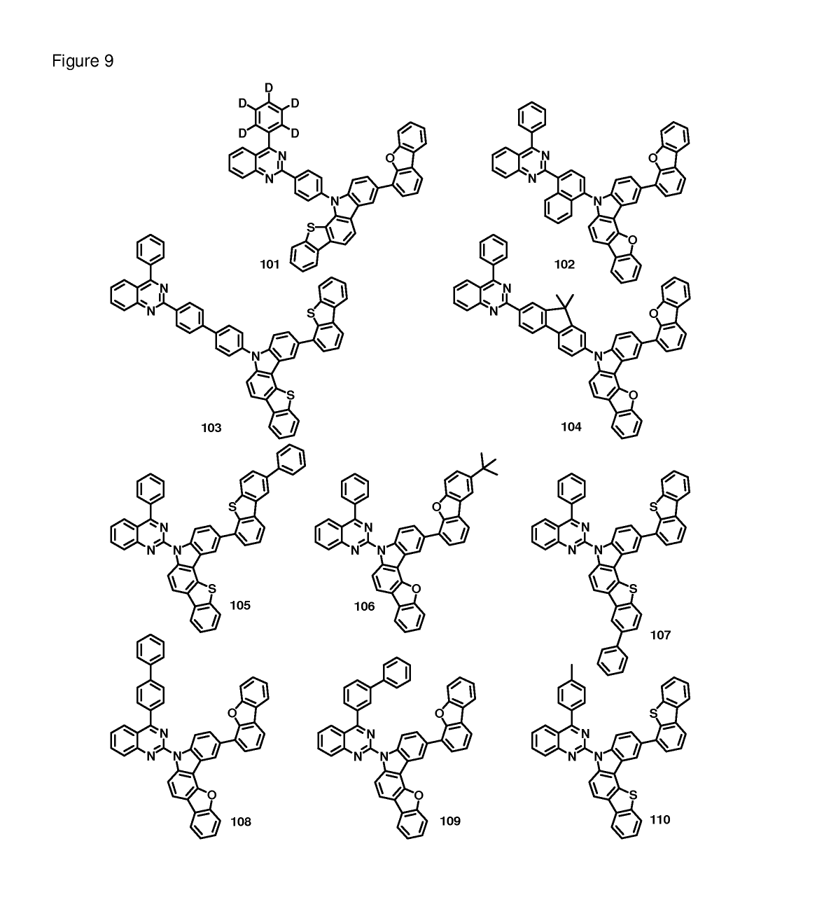

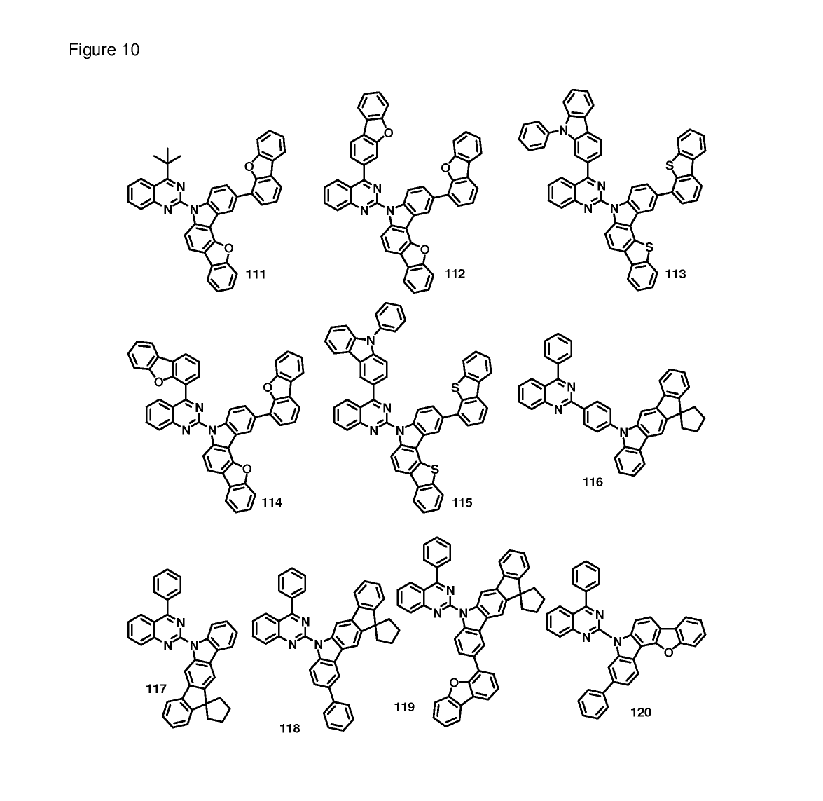

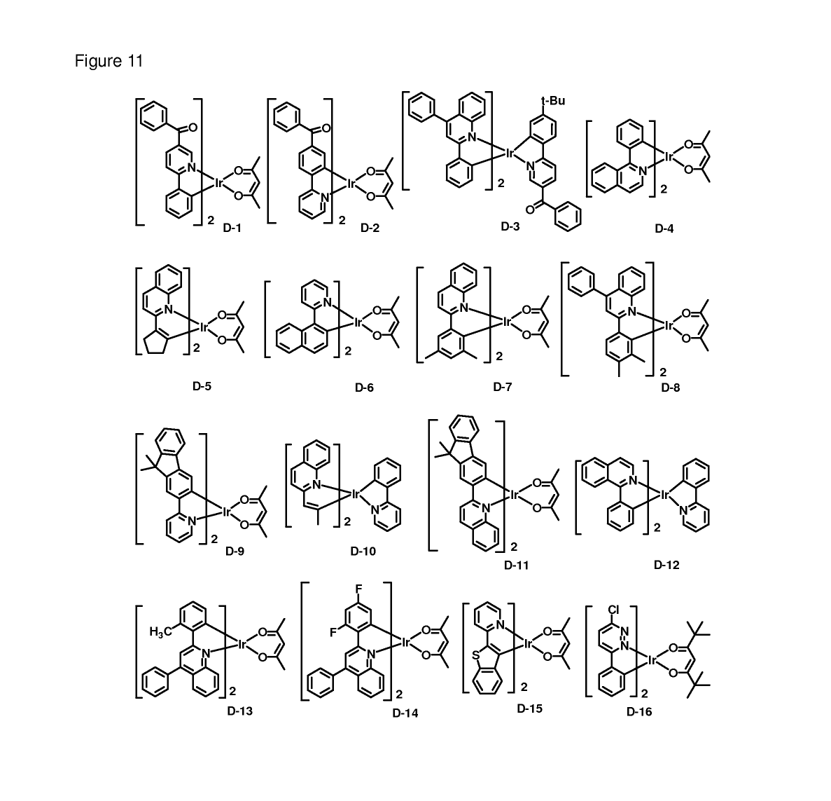

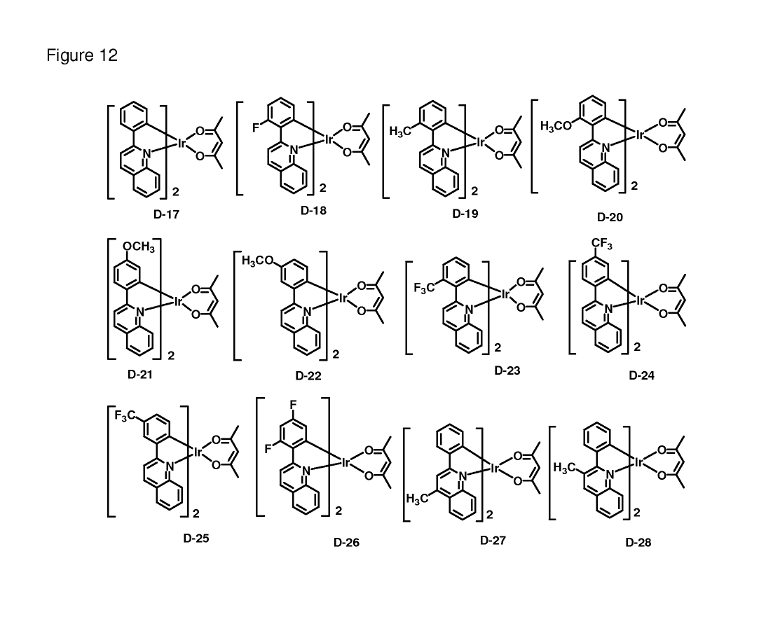

### MODE FOR THE INVENTION

Hereinafter, the present invention is further described by taking representative compounds of the present invention as examples of the compounds for an organic electronic material according to the invention, a method of preparation thereof, and electroluminescent properties of the devices. But, those examples are provided only for the sake of illustrating the embodiments, and are not intended to limit the scope of the invention.

### Preparation Example 1

### Preparation of Compound 1

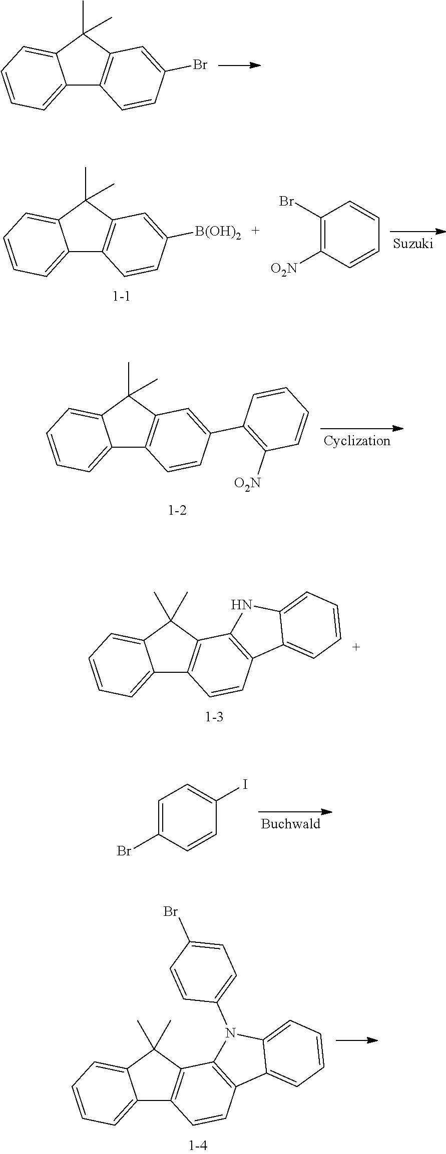

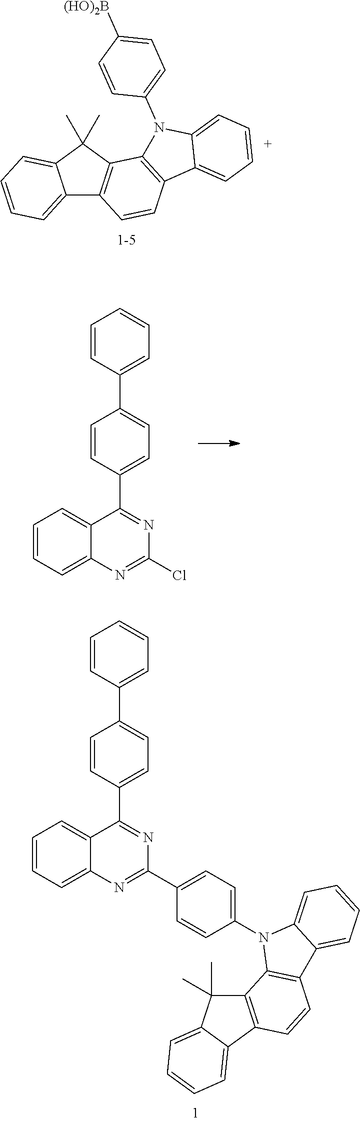

### Preparation of Compound 1-1

At −78° C. in a nitrogen atmosphere, 9,9-dimethyl-2-bromofluorene (30 g, 109.8 mmol) was dissolved in THF 500 mL, and 2.5M n-BuLi(2.5M in hexane, 20.7 mL, 142.7 mmol) was added. This mixture was stirred for 1 hour. B(OMe)₃ (20.7 mL, 186.7 mmol) was slowly added, and the mixture was stirred for one day. The mixture was quenched with 1M HCl, extracted with distilled water and EA, and recrystallized from hexane and MC, yielding Compound 1-1 (16.2 g, 62.0%).

### Preparation of Compound 1-2

Compound 1-1 (20 g, 84 mmol), 1-bromo-2-nitrobenzene (14.1 g, 70 mmol), Pd(PPh₃)₄ (4 g, 34.6 mmol), and Na₂CO₃ (22.3 g, 210 mmol) was dissolved in a mixture comprising toluene (400 mL), EtOH (100 mL) and distilled water (100 mL), and then stirred at 120° C. for 6 hours. The mixture was extracted with EA and distilled water and column chromatography was performed, yielding Compound 1-2 (21.7 g, 98.3%).

### Preparation of Compound 1-3

Compound 1-2 (21.7 g, 68.8 mmol) was dissolved in triethylphosphite (200 mL) and 1,2-dichlorobenzene (150 mL) and stirred at 160° C. for one day. The mixture was distilled in a vacuum to remove triethylphosphite and 1,2-dichlorobenzene, extracted with MC and distilled water, and triturated with MC. The filtrate was separated using column chromatography, yielding Compound 1-3 (8 g, 41%).

### Preparation of Compound 1-4

Compound 1-3 (10 g, 35.3 mmol), 1-bromo-4-iodobenzene (29.9 g, 105.9 mmol), Pd(OAc)₂ (2.4 g, 10.6 mmol), and NaOt-Bu (16.9 g, 176.5 mmol) were dissolved in toluene (180 mL), and P(t-Bu)₃ (4.2 mL, 17.6 mmol) was added. The mixture was stirred at 90° C. for three days, cooled to room temperature, and extracted with EA and distilled water. Subsequently, column chromatography was performed, yielding Compound 1-4 (9.4 g, 60.6%).

### Preparation of Compound 1-5

Compound 1-4 (8.4 g, 19.2 mmol) was dissolved in THF (500 mL), and n-BuLi (2.5M in hexane, 11.5 ml, 28.7 mmol) was added at −78° C. in a nitrogen atmosphere. The mixture was stirred for 1 hour, and B(Oi—Pr)₃ was added. The mixture was stirred for 5 hours, quenched with 1N HCl, extracted with EA and distilled water, and recrysallized from MC and hexane, yielding Compound 1-5 (5 g, 57.8%).

### Preparation of Compound 1

Compound 1-5 (5 g, 12.4 mmol), 4-(biphenyl-4-yl)-2-chloroquinazoline (2.62 g, 8.3 mmol), Pd(PPh₃)₄ (600 mg, 0.52 mmol), and Na₂CO₃ (2.63 g, 24.8 mmol) were dissolved in a mixture comprising toluene (300 mL), EtOH (100 mL) and distilled water (100 mL) and stirred at 120° C. for one day. The mixture was cooled to room temperature, extracted with EA and distilled water, dissolved in chloroform to perform silica filtration, and recrystallized from MC and hexane. Further, two recrysallizations from DMF were carried out, followed by performing trituration with MeOH/EA, yielding Compound 1 (3.2 g, 60.4%).

MS/EIMS: 639.79 (exp.), 639.27 (calculated)

### Preparation Example 2

### Preparation of Compound 49

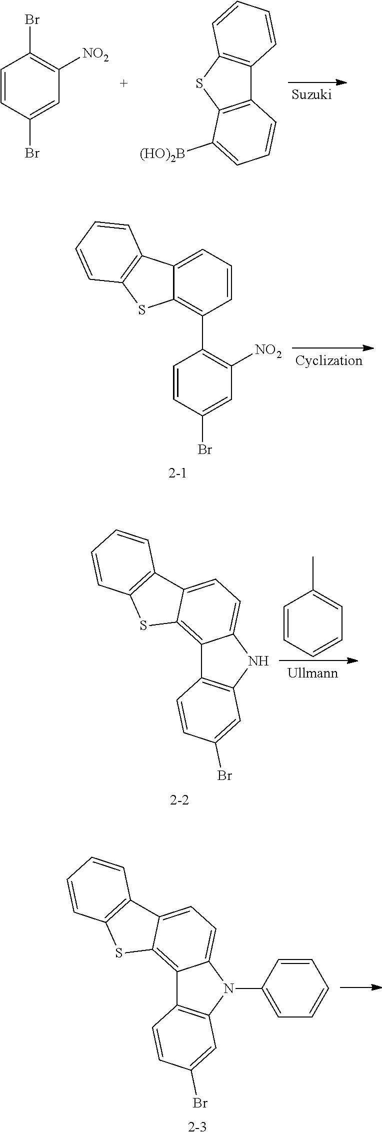

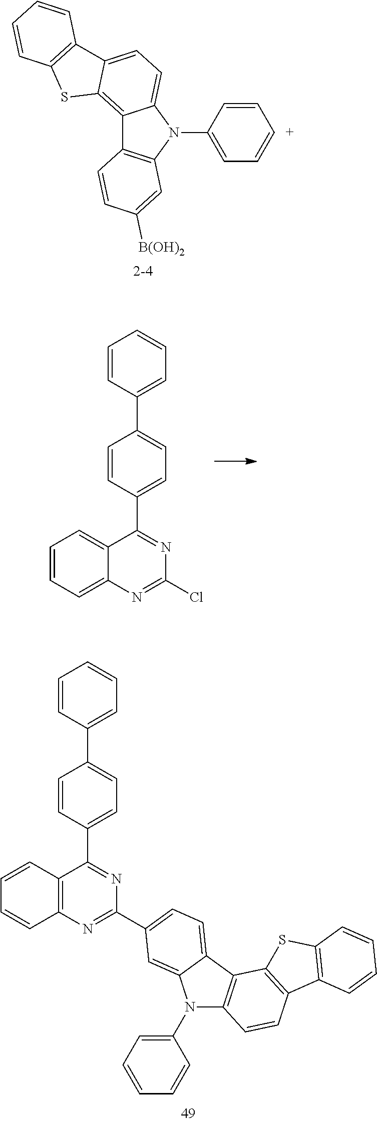

Compound 2-1 was prepared in the same manner as Compound 1-2, and Compound 2-2 was prepared in the same manner as Compound 1-3.

### Preparation of Compound 2-3

Compound 2-2 (7 g, 25.60 mmol), iodobenzene (10.44 g, 51.21 mmol), CuI (2.5 g, 12.80 mmol), K₃PO₄ (16.30 g, 76.82 mmol) and toluene (200 mL) were heated to 50° C., and ethylenediamine (1.72 mL, 25.60 mmol) was add. The mixture was stirred under reflux for 12 hours, cooled to room temperature, and extracted with EA. Column separation was conducted, yielding Compound 2-3 (8 g, 22.89 mmol, 89.41%).

Compound 2-4 was prepared in the same manner as Compound 1-4.

### Preparation of Compound 49

4-(biphenyl-4-yl)-2-chloroquinazoline (2.1 g, 6.56 mol), Compound 2-4 (3.1 g, 7.88 mmol), Pd(PPh₃)₄ (379.5 mg, 0.3285 mmol), 2M K₂CO₃ (16 mL) and toluene were added. The mixture was stirred for 12 hours at 100° C., and cooled to room temperature. The distilled water was added and the mixture was extracted with EA. Column separation was conducted, yielding Compound 49 (1.15 g, 28% yield).

MS/EIMS: 629.77 (found), 629.19 (calculated)

### Preparation Example 3

### Preparation of Compound 51

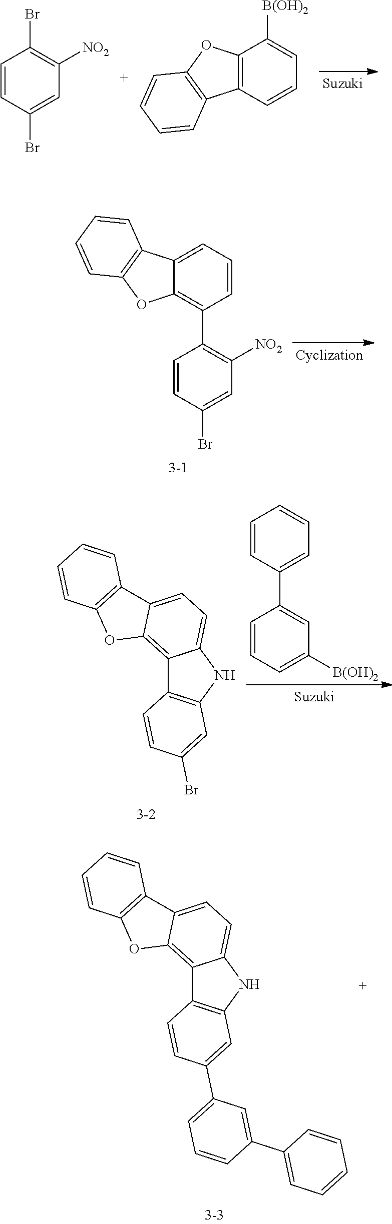

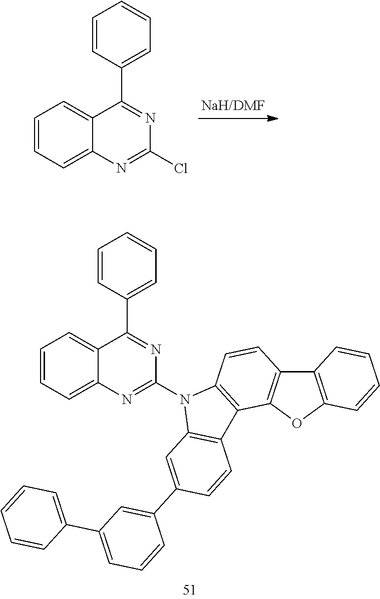 [SMILES: Clc1nc(-c2ccccc2)c2ccccc2n1 ; c1ccc(-c2cccc(-c3ccc4c5c6oc7ccccc7c6ccc5n(-c5nc(-c6ccccc6)c6ccccc6n5)c4c3)c2)cc1]

Compound 3-1 was prepared in the same manner as Compound 1-2; Compound 3-2 was prepared in the same manner as Compound 1-3; and Compound 3-3 was prepared in the same manner as Compound 1-2.

### Preparation of Compound 51

Compound 3-3 (4.3 g, 10.5 mol) and DMF (100 mL) were mixed, and NaH (0.5 g, 12.6 mmol, 60% dispersion in mineral oil) was slowly added to the mixture. The mixture was stirred at room temperature. Upon completion of the reaction, 2-chloro-4-phenylquinazoline (2.5 g, 10.5 mmol) was slowly added to the reaction mixture and stirred at 50° C. for 3 hours. After stirring, a solid product was obtained by adding MeOH and distilled water to the reaction mixture. Column separation was conducted on the solid product, yielding Compound 51 (4.3 g, 66%).

MS/EIMS: 613.70 (found), 613.22 (calculated)

### Preparation Examples 4 to 10

### Preparation of Compound 52, Compound 53, Compound 54, Compound 56, Compound 86, Compound 108 and Compound 109

Compound 52 (Preparation Example 4), Compound 53 (Preparation Example 5), Compound 54 (Preparation Example 6), Compound 56 (Preparation Example 7),

Compound 86 (Preparation Example 8), Compound 108 (Preparation Example 9) and Compound 109 (Preparation Example 10) were prepared in the same manner as Compound 51.

### Preparation Example 11

### Preparation of Compound 50

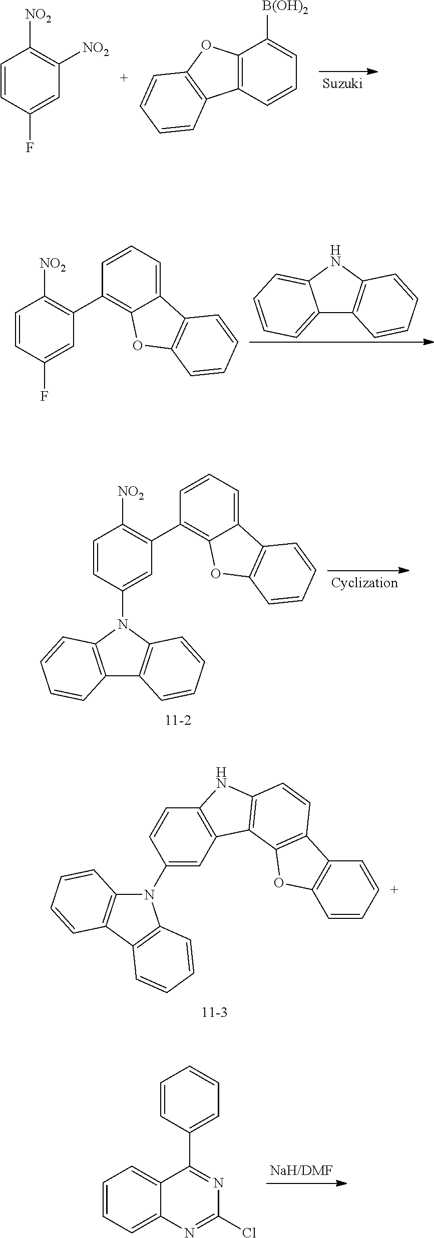

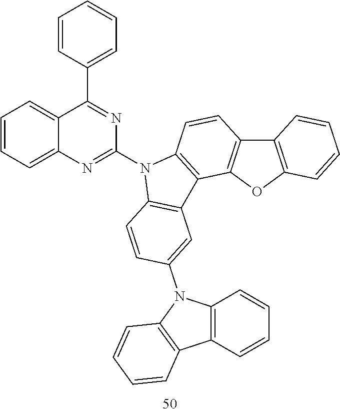 [SMILES: c1ccc(-c2nc(-n3c4ccc(-n5c6ccccc6c6ccccc65)cc4c4c5oc6ccccc6c5ccc43)nc3ccccc23)cc1]

Compound 11-1 was prepared in the same manner as Compound 1-2.

### Preparation of Compound 11-2

Carbazole (3.3 g, 19.9 mol) and DMF (100 mL) were mixed, and NaH (0.95 g, 24 mmol, 60% dispersion in mineral oil) was slowly added to the mixture. The mixture was stirred at room temperature. Upon completion of the reaction, Compound 11-1 (6.1 g, 19.9 mmol) was slowly added to the reaction mixture and stirred at room temperature for 3 hours. After stirring, a solid product was obtained by adding distilled water to the reaction mixture. The solid product was filtered, yielding Compound 11-2 (9 g, quantitative yield).

Compound 11-3 was prepared in the same manner as Compound 1-3.

### Preparation of Compound 50

Compound 11-3 (5.7 g, 13.5 mol) and DMF (100 mL) were mixed, and NaH (0.65 g, 16.2 mmol, 60% dispersion in mineral oil) was slowly added to the mixture. The mixture was stirred at room temperature for 40 minutes. Upon completion of the reaction, 2-chloro-4-phenylquinazoline (3.25 g, 13.5 mmol) was slowly added to the reaction mixture and stirred at 50° C. for 3 hours. After stirring, a solid product was obtained by adding MeOH and distilled water to the reaction mixture. Column separation was conducted on the solid product, yielding Compound 50 (5.7 g, 68%).

MS/EIMS: 626.70 (found), 626.21 (calculated)

### Preparation Example 12

### Preparation of Compound 3

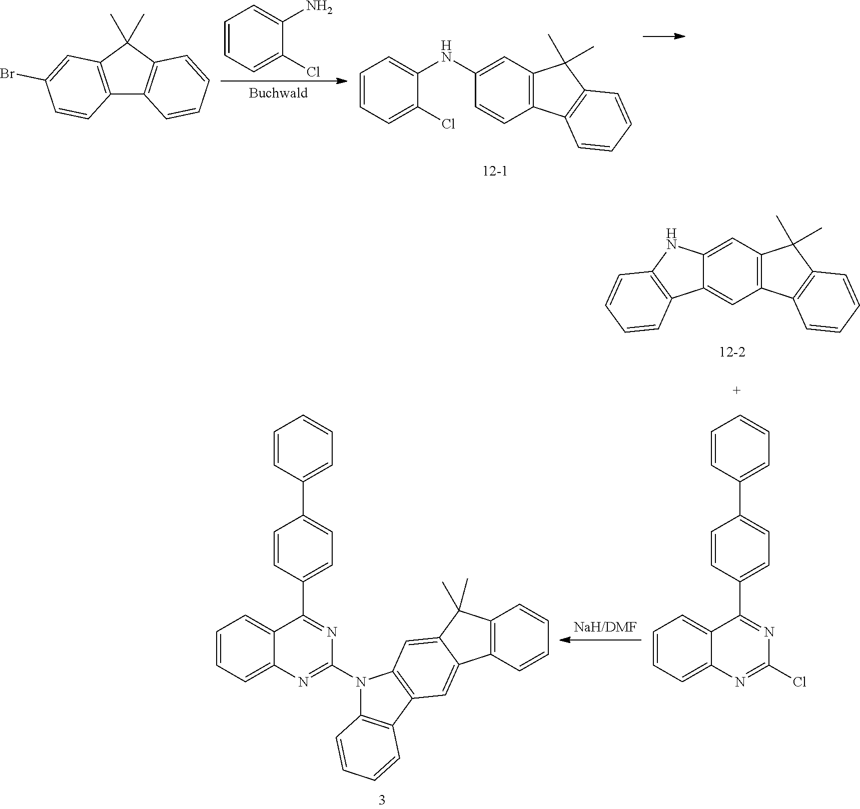

Compound 12-1 was prepared in the same manner as Compound 1-4.

### Preparation of Compound 12-2

Compound 12-1 (70 g, 218 mmol), Pd(OAc)₂ (2.4 g, 11 mmol) tricyclohexylphosphine tetrafluoroborate (8 g, 22 mmol), Na₂CO₃ (70 g, 654 mmol) and DMA (1.2 L) were mixed, and stirred at 190° C. for 3 hours. After stirring, the reaction mixture was cooled to room temperature and extracted with EA. Column separation was conducted on the solid product, yielding Compound 12-2 (22 g, 36%).

### Preparation of Compound 3

Compound 12-2 (5 g, 17.64 mmol) and DMF (100 mL) were mixed, and NaH (1.1 g, 26.46 mmol, 60% dispersion in mineral oil) was slowly added to the mixture. The mixture was stirred at room temperature for 30 minutes. After stirring, 4-(biphenyl-4-yl)-2-chloroquinazoline (5.6 g, 17.64 mmol) was slowly added to the mixture and stirred for 4 hours. After stirring, a solid product was obtained by adding distilled water (300 mL) to the reaction mixture and stirring the reaction mixture for 30 minutes. Column separation was conducted on the solid product, yielding Compound 3 (6.9 g, 70%).

MS/EIMS: 563.69 (found), 563.24 (calculated)

### Preparation Example 13

### Preparation of Compound 64

Compound 64 was prepared in the same manner as Compound 3.

### Preparation Example 14

### Preparation of Compound 4

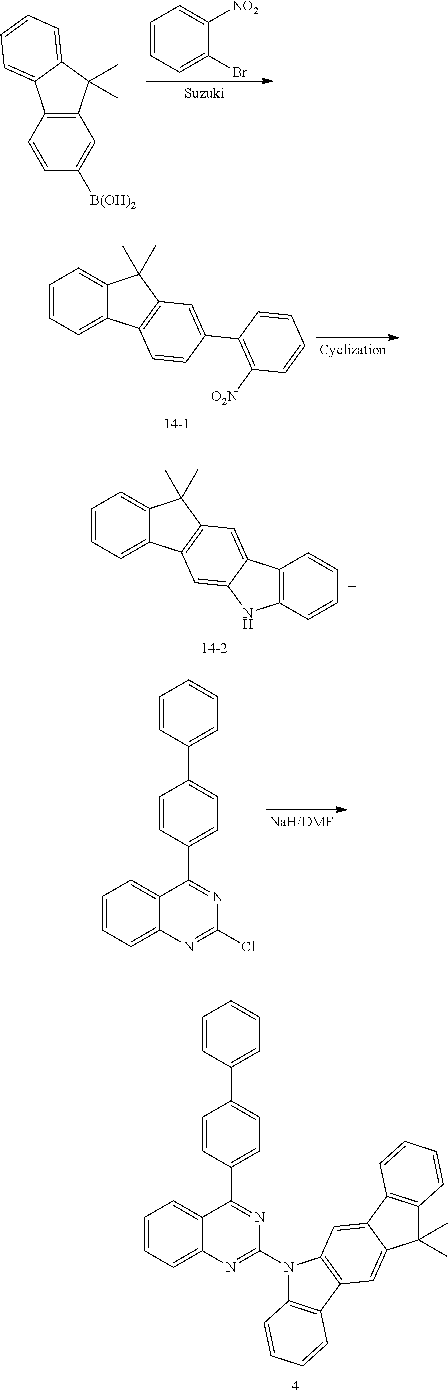

Compound 14-1 was prepared in the same manner as Compound 1-2, and Compound 14-2 was prepared in the same manner as Compound 1-3.

### Preparation of Compound 4

After Compound 14-2 (5.75 g, 20.3 mmol) was dissolved in DMF (50 mL), NaH (1 g, 27.6 mmol) was slowly added and stirred for 40 minutes. After stirring, 4-(biphenyl-4-yl)-2-chloroquinazoline (5.84 g, 18.4 mmol) was slowly added to the mixture and stirred at room temperature for 24 hours. Upon completion of the reaction, distilled water (300 mL) was slowly added to the reaction mixture and stirred for 30 minutes to produce a solid product. Column separation was conducted on the solid product, yielding Compound 4 (6.5 g, 65%).

MS/EIMS: 563.69 (found), 563.24 (calculated)

### Preparation Examples 15 to 24

### Preparation of Compound 12, Compound 18, Compound 62, Compound 63, Compound 65, Compound 66, Compound 74, Compound 75, Compound 76 and Compound 77

Compound 12 (Preparation Example 15), Compound 18 (Preparation Example 16), Compound 62 (Preparation Example 17), Compound 63 (Preparation Example 18), Compound 65 (Preparation Example 19), Compound 66 (Preparation Example 20), Compound 74 (Preparation Example 21), Compound 75 (Preparation Example 22), Compound 76 (Preparation Example 23) and Compound 77 (Preparation Example 24) were prepared in the same manner as Compound 4.

### Preparation Example 25

### Preparation of Compound 19

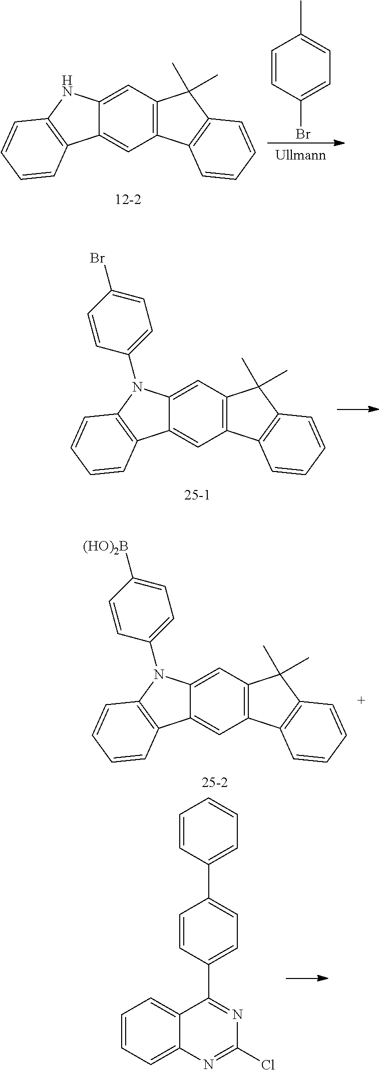

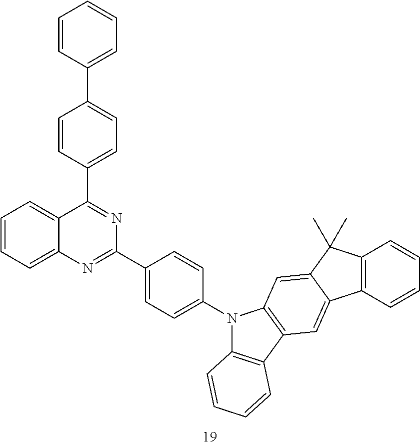 [SMILES: CC1(C)c2ccccc2-c2cc3c4ccccc4n(-c4ccc(-c5nc(-c6ccc(-c7ccccc7)cc6)c6ccccc6n5)cc4)c3cc21]

Compound 25-1 was prepared in the same manner as Compound 2-3, and Compound 25-2 was prepared in the same manner as Compound 1-4.

### Preparation of Compound 19

Compound 25-2 (6.8 g, 16.86 mmol), 4-(biphenyl-4-yl)-2-chloroquinazoline (4 g, 12.97 mmol), Pd(PPh₃)₄ (0.8 g, 0.65 mmol), Na₂CO₃ (4.2 g, 38.91 mmol), toluene (70 mL), ethanol (20 mL) and distilled water (20 mL) were mixed and stirred at 120° C. for 5 hours. The mixture was cooled to room temperature and distilled water was added. The mixture was extracted with EA. Column separation was conducted, yielding Compound 19 (1.0 g, 12%).

MS/EIMS: 639.79 (found), 639.27 (calculated)

Table 1 shows a UV value, a PL value and mp of Compounds according to the present invention.

TABLE 1

| | UV | PL | mp |
|---|---|---|---|
| Compound | (nm) | (nm) | (° C.) |
| 1 | 368 | 433 | 212 |
| 3 | 356 | 521 | 255 |
| 4 | 354 | 480 | 253 |
| 12 | 340 | 498 | 275 |
| 18 | 322 | 492 | 288 |
| 19 | 358 | 445 | 218 |
| 31 | 402 | 431 | 246 |
| 49 | 336 | 441 | 352 |
| 50 | 290 | 509 | 308 |
| 51 | 308 | 487 | 231 |
| 52 | 312 | 497 | 274 |
| 53 | 310 | 493 | 242 |
| 54 | 308 | 487 | 247 |
| 56 | 290 | 511 | 292 |
| 62 | 344 | 497 | 222 |
| 63 | 292 | 509 | 173 |
| 64 | 307 | 390 | 190 |
| 65 | 342 | 487 | 227 |
| 66 | 346 | 497 | 246 |
| 74 | 344 | 497 | 242 |
| 75 | 282 | 519 | 251 |
| 76 | 360 | 483 | 247 |
| 77 | 338 | 503 | 255 |
| 86 | 310 | 495 | 275 |
| 108 | 310 | 504 | 256 |
| 109 | 308 | 486 | 253 |

### Example 1

### Manufacture of OLED Device Using the Compound for an Organic Electronic Material According to the Present Invention

An OLED device was manufactured by using the electroluminescent material according to the present invention. First, a transparent electrode ITO thin film (15Ω/□) obtained from a glass for OLED (manufactured by Samsung Corning) was subjected to ultrasonic washing with trichloroethylene, acetone, ethanol and distilled water, sequentially, and stored in isopropanol before use. Then, the ITO substrate was equipped in a substrate holder of a vacuum vapor deposition apparatus, and N¹,N^{1′}-([1,1′-biphenyl]-4,4′-diyl)bis(N¹-(naphthalen-1-yl)-N⁴,N⁴-diphenylbenzene-1,4-diamine) was placed in a cell of the vacuum vapor deposition apparatus, which was then ventilated up to 10⁻⁶ torr of vacuum in the chamber. Then, electric current was applied to the cell to evaporate 2-TNATA, thereby forming a hole injection layer having a thickness of 60 nm on the ITO substrate. Then, N,N′-di(4-biphenyl)-N,N′-di(4-biphenyl)-4,4′-diaminobiphenyl was placed in another cell of the vacuum vapor deposition apparatus, and electric current was applied to the cell to evaporate NPB, thereby forming a hole transport layer having a thickness of 20 nm on the hole injection layer. After forming the hole injection layer and the hole transport layer, an electroluminescent layer was formed thereon as follows. Compound 3 according to the present invention as a host was placed in a cell, and D-11 as a dopant was placed in another cell, within a vacuum vapor deposition apparatus. The two materials were evaporated at different rates such that 4 wt % doping taken place, and thereby the electroluminescent layer having a thickness of 30 nm was vapor-deposited on the hole transport layer. Subsequently, 2-(4-(9,10-di(naphthalen-2-yl)anthracen-2-yl)phenyl)-1-phenyl-1H-benzo[d]imidazole was placed in a cell and lithium quinolate was placed in another cell, after which the two materials were evaporated at the same rate such that 50 wt % doping taken place, and thereby an electron transport layer was vapor-deposited to a thickness of 30 nm on the electroluminescent layer. Subsequently, lithium quinolate (Liq) was vapor-deposited to a thickness of 2 nm as an electron injection layer, after which an Al cathode having a thickness of 150 nm was vapor-deposited using another vacuum vapor deposition apparatus to manufacture an OLED device.

Each compound used in the OLED device as the electroluminescent material was purified by vacuum sublimation at 10⁻⁶ torr before use.

As a result, the flow of current of 17.0 mA/cm² was confirmed and a red light of 780 cd/m² was emitted.

### Example 2

### Manufacture of OLED Device Using Compound for Organic Electronic Material According to Present Invention

An OLED device was manufactured by the same method as Example 1 except that Compound 12 was used as a host material in the electroluminescent layer and Compound D-7 was used as a dopant.

As a result, the flow of current of 7.5 mA/cm² was confirmed and a red light of 1057 cd/m² was emitted.

### Example 3

### Manufacture of OLED Device Using Compound for Organic Electronic Material According to Present Invention

An OLED device was manufactured by the same method as Example 1 except that Compound 31 was used as a host material in the electroluminescent layer and Compound D-7 was used as a dopant.

As a result, the flow of current of 8.3 mA/cm² was confirmed and a red light of 930 cd/m² was emitted.

### Example 4

### Manufacture of OLED Device Using Compound for Organic Electronic Material According to Present Invention

An OLED device was manufactured by the same method as Example 1 except that Compound 51 was used as a host material in the electroluminescent layer and Compound D-11 was used as a dopant.

As a result, the flow of current of 16.0 mA/cm² was confirmed and a red light of 1090 cd/m² was emitted.

### Example 5

### Manufacture of OLED Device Using Compound for Organic Electronic Material According to Present Invention

An OLED device was manufactured by the same method as Example 1 except that Compound 63 was used as a host material in the electroluminescent layer and Compound D-11 was used as a dopant.

As a result, the flow of current of 14.5 mA/cm² was confirmed and a red light of 1380 cd/m² was emitted.

### Example 6

### Manufacture of OLED Device Using Compound for Organic Electronic Material According to Present Invention

An OLED device was manufactured by the same method as Example 1 except that Compound 77 was used as a host material in the electroluminescent layer and Compound D-7 was used as a dopant.

As a result, the flow of current of 19.8 mA/cm² was confirmed and a red light of 3200 cd/m² was emitted.

### Example 7

### Manufacture of OLED Device Using Compound for Organic Electronic Material According to Present Invention

An OLED device was manufactured by the same method as Example 1 except that Compound 109 was used as a host material in the electroluminescent layer and Compound D-7 was used as a dopant.

As a result, the flow of current of 9.2 mA/cm² was confirmed and a red light of 1250 cd/m² was emitted.

### Comparative Example 1

### Manufacture of OLED Device Using Conventional Luminescent Material

An OLED device was manufactured by the same method as Example 1 except that 4,4′-N,N′-dicarbazole-biphenyl was used as a host material in the electroluminescent layer and Compound D-11 was used as a dopant to vapor-deposit the electroluminescent layer and that aluminum(III)bis(2-methyl-8-quinolinato)₄-phenylphenolate having a thickness of 10 nm was deposited as a hole blocking layer between the electroluminescent layer and the electron transport layer.

As a result, the flow of current of 20.0 mA/cm² was confirmed and a red light of 1000 cd/m² was emitted.

It was confirmed that the compound for organic electronic material developed in the present invention as a red electroluminescent material showed superior electroluminescent properties compared to the conventional materials. Devices using the compound for organic electronic material of the present invention as a host material can exhibit superior electroluminescent properties and can reduce operating voltage to thus increase power efficiency, and thereby consumes less power.

Although the preferred embodiments of the present invention have been disclosed for illustrative purposes, those skilled in the art will appreciate that various modifications, additions, and substitutions are possible, without departing from the scope and spirit of the invention as disclosed in the accompanying claims.

### INDUSTRIAL APPLICABILITY

According to the present invention, compounds for an organic electronic material can be used to manufacture OLED devices having improved power efficiency as well as reduced operating voltage while exhibiting good luminous efficiency.

1. A compound for an organic electronic material, represented by Chemical Formula 1 below: 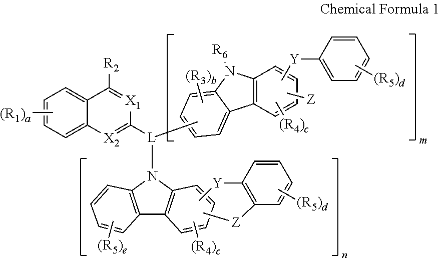
In Chemical Formula 1, L represents a single bond, (C6-C30)arylene or (C2-C30)heteroarylene;
X₁ and X₂ independently represent CR′ or N, in which both X₁ and X₂ are not CR′;
one of Y and Z is essentially a single bond, and the other is —C(R₇)(R₈)—, —N(R₉)—, —O—, —S— or —Si(R₁₀)(R₁₁)—;
R′, R₁ through R₆ independently represent hydrogen, deuterium, (C1-C30)alkyl, halo(C1-C30)alkyl, halogen, cyano, (C3-C30)cycloalkyl, 5- to 7-membered heterocycloalkyl, (C2-C30)alkenyl, (C2-C30)alkynyl, (C6-C30)aryl, (C2-C30)heteroaryl, (C6-C30)ar(C1-C30)alkyl, N-carbazolyl, —NR₁₂R₁₃, —SiR₁₄R₁₅R₁₆, —SR₁₇, —OR₁₈, nitro or hydroxyl;
R₇ through R₁₁ and R₁₂ through R₁₈ independently represent hydrogen, deuterium, halogen, (C1-C30)alkyl, (C6-C30)aryl or (C2-C30)heteroaryl, and R₇ and R₈ may be linked via (C3-C30)alkylene or (C3-C30)alkenylene with or without a fused ring to form a Spiro ring;
the arylene and heteroarylene of L and L₁ and the alkyl, cycloalkyl, heterocycloalkyl, alkenyl, alkynyl, aryl and heteroaryl of R′, R₁ through R₆ may be independently further substituted with one or more selected from the group consisting of deuterium, (C1-C30)alkyl, halo(C1-C30)alkyl, halogen, cyano, (C3-C30)cycloalkyl, 5- to 7-membered heterocycloalkyl, (C2-C30)alkenyl, (C2-C30)alkynyl, (C6-C30)aryl, (C1-C30)alkoxy, (C6-C30)aryloxy, (C2-C30)heteroaryl, (C6-C30)aryl-subsititued (C2-C30)heteroaryl, (C6-C30)ar(C1-C30)alkyl, (C1-C30)alkyl(C6-C30)aryl, (C6-C30)arylthio, mono or di(C1-C30)alkylamino, mono or di(C6-C30)arylamino, (C1-C30)alkyl(C6-C30)arylamino, di(C6-C30)arylboronyl, di(C1-C30)alkylboronyl, (C1-C30)alkyl(C6-C30)arylboronyl, tri(C1-C30)alkylsilyl, di(C1-C30)alkyl(C6-C30)arylsilyl, (C1-C30)alkyldi(C6-C30)arylsilyl, tri(C6-C30)arylsilyl, N-carbazolyl, carboxyl, nitro and hydroxyl;
a, d and e independently represent an integer of 1 to 4, and when they are integers of 2 or larger, each substituent may be identical or different from each other;
b represents an integer of 1 to 3, and when they are integers of 2 or larger, each substituent may be identical or different from each other;
c represents an integer of 1 to 2, and when they are integers of 2 or larger, each substituent may be identical or different from each other;
m and n independently represent an integer of 0 or 1, and m+n equals to 1;
the heteroarylene, heterocycloalkyl and heteroaryl include one or more heteroatoms selected from the group consisting of B, N, O, S, P(═O), Si and P.

2. The compound for an organic electronic material of claim 1, which is represented by Chemical Formula 2 or 3 below. 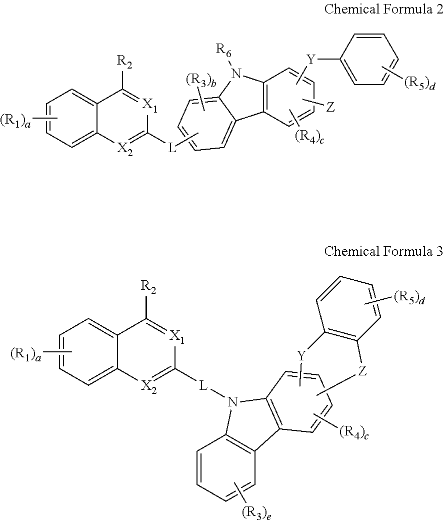
wherein R₁ through R₆, X₁, X₂, L, Y, Z, a, b, c, d and e are same as defined in claim 1.

3. The compound for an organic electronic material of claim 1, which is represented by Chemical Formula 4: 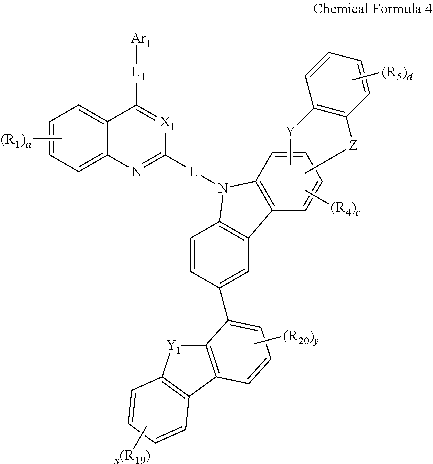
wherein R₁, R₄, R₅, L, X₁, Y, Z, a, c and d are the same as defined in claim 1; R₁₉ and R₂₀ independently represent hydrogen, deuterium, (C1-C30)alkyl, halo(C1-C30)alkyl, halogen, cyano, (C3-C30)cycloalkyl, 5- or 7-membered heterocycloalkyl, (C2-C30)alkenyl, (C2-C30)alkynyl, (C6-C30)aryl, (C2-C30)heteroaryl, (C6-C30)ar(C1-C30)alkyl, —NR₁₂R₁₃, —SiR₁₄R₁₅R₁₆, —SR₁₇, —OR₁₈, nitro or hydroxyl; R₁₂ through R₁₈ are the same as defined in claim 1; L₁ represents a single bond, (C2-C30)heteroarylene or (C6-C30)arylene; Ar₁ represents hydrogen, deuterium, (C2-C30)heteroaryl, (C6-C30)aryl or (C1-C30)alkyl; Y₁ represents —O—, —S—, —CR₂₁R₂₂— or —NR₂₃—, R₂₁ through R₂₃ independently represent hydrogen, deuterium, halogen, (C1-C30)alkyl, (C6-C30)aryl or (C2-C30)heteroaryl; x and y independently represent an integer of 1 to 4; arylene, heteroarylene of the L₁, alkyl, cycloalkyl, heterocycloalkyl, alkenyl, alkynyl, aryl, heteroaryl, aralkyl of R₁₉ and R₂₀, and heteroaryl, aryl or alkyl of Ar₁, alkyl, aryl or heteroaryl of R₂₁ through R₂₂ may be independently further substituted with one or more selected from the group consisting of deuterium, (C1-C30)alkyl, halo(C1-C30)alkyl, halogen, cyano, (C3-C30)cycloalkyl, 5- or 7-membered heterocycloalkyl, (C2-C30)alkenyl, (C2-C30)alkynyl, (C6-C30)aryl, (C1-C30)alkoxy, (C6-C30)aryloxy, (C2-C30)heteroaryl, (C6-C30)aryl-substituted (C3-C30)heteroaryl, (C6-C30)ar(C1-C30)alkyl, (C1-C30)alkyl(C6-C30)aryl, (C6-C30)arylthio, mono or di(C1-C30)alkylamino, mono or di(C6-C30)arylamino, (C1-C30)alkyl(C6-C30)arylamino, di(C6-C30)arylboronyl, di(C1-C30)alkylboronyl, (C1-C30)alkyl(C6-C30)arylboronyl, tri(C1-C30)alkylsilyl, di(C1-C30)alkyl(C6-C30)arylsilyl, (C1-C30)alkyldi(C6-C30)arylsilyl, tri(C6-C30)arylsilyl, N-carbazolyl, carboxyl, nitro and hydroxyl.

4. The compound for an organic electronic material of claim 1, wherein the 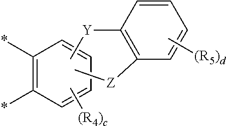
is selected from following structures: 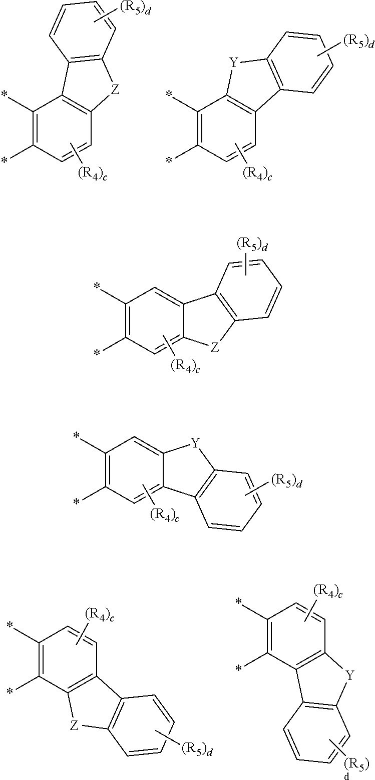
wherein, the Y, Z, R₄, R₅, c and d are the same as defined in claim 1.

5. The compound for an organic electronic material of claim 1, wherein L represents a single bond or (C6-C30)arylene; X₁ and X₂ independently represent CH or N, wherein both X₁ and X₂ are not CH; one of Y and Z is essentially a single bond, and the other is —C(R₇)(R₈)—, —N(R₉)—, —O— or —S—; and R₁ through R₆ independently represent hydrogen, deuterium, (C1-C30)alkyl, halo(C1-C30)alkyl (C6-C30)aryl, (C2-C30)heteroaryl or N-carbazolyl; R₇ through R₉ independently represent (C1-C30)alkyl or (C6-C30)aryl, and R₇ and R₈ may be linked via (C3-C7)alkylene to form a Spiro ring; arylene of the L, alkyl, aryl, or heteroaryl of R₁ through R₆ and alkyl or aryl of R₇ through R₉ may be independently substituted with one or more selected from the group consisting of deuterium, (C1-C30)alkyl, halo(C1-C30)alkyl, halogen, (C6-C30)aryl, (C2-C30)heteroaryl and N-carbazolyl.

6. The compound for an organic electronic material of claim 3, wherein the L₁ represents a single bond, (C2-C30)heteroarylene or (C6-C30)arylene; Ar₁ represents hydrogen, deuterium, (C2-C30)heteroaryl, (C6-C30)aryl or (C1-C30)alkyl; Y₁ represents —O—, —S—, —CR₂₁R₂₂— or —NR₂₃—, R₂₁ through R₂₃ independently represent hydrogen, deuterium, (C1-C30)alkyl, (C6-C30)aryl or (C2-C30)heteroaryl; R₁₉ and R₂₀ independently represent hydrogen, deuterium, halogen, (C1-C30)alkyl, (C6-C30)aryl or (C2-C30)heteroaryl; L represents a single bond or (C6-C30)arylene; X₂ represents CH or N; at least one of Y and Z represents a single bond, and the other represents —C(R₇)(R₈)—, —N(R₉)—, —O— or —S—; R₁, R₄ and R₅ independently represent hydrogen, deuterium, (C1-C30)alkyl, halo(C1-C30)alkyl, (C6-C30)aryl, (C2-C30)heteroaryl or N-carbazolyl; R₇ through R₉ independently represent (C1-C30)alkyl or (C6-C30)aryl, and R₇ and R₈ may be linked via (C3-C7)alkylene to form a spiro ring; arylene of the L, heteroarylene or arylene of L₁, alkyl, aryl, heteroaryl of R₁, R₄, R₅, Ar₁, R₁₉, R₂₀, and R₂₁ through R₂₃, and alkyl or aryl of R₇ through R₉ may be independently further substituted with one or more selected from the group consisting of deuterium, (C1-C30)alkyl, halo(C1-C30)alkyl, halogen, (C6-C30)aryl, (C2-C30)heteroaryl and N-carbazolyl.

7. The compound for an organic electronic material of claim 1, which is selected from following structure:

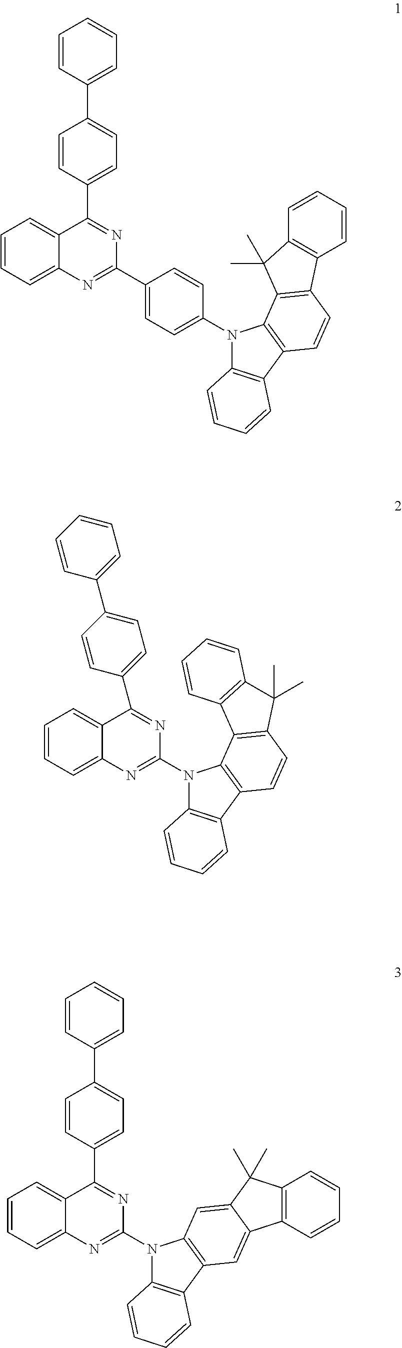 [SMILES: CC1(C)c2ccccc2-c2ccc3c4ccccc4n(-c4ccc(-c5nc(-c6ccc(-c7ccccc7)cc6)c6ccccc6n5)cc4)c3c21 ; CC1(C)c2ccccc2-c2c1ccc1c3ccccc3n(-c3nc(-c4ccc(-c5ccccc5)cc4)c4ccccc4n3)c21 ; CC1(C)c2ccccc2-c2cc3c4ccccc4n(-c4nc(-c5ccc(-c6ccccc6)cc5)c5ccccc5n4)c3cc21]

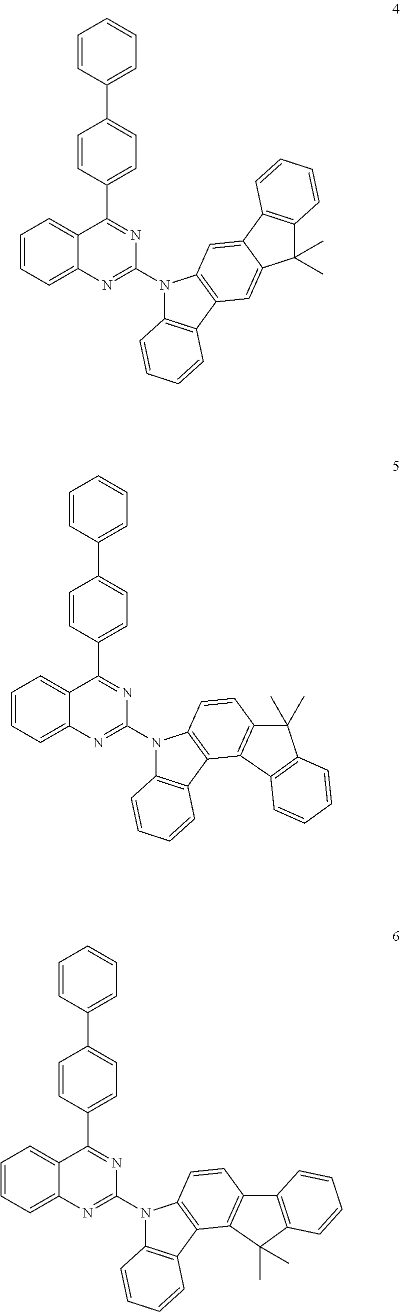 [SMILES: CC1(C)c2ccccc2-c2cc3c(cc21)c1ccccc1n3-c1nc(-c2ccc(-c3ccccc3)cc2)c2ccccc2n1 ; CC1(C)c2ccccc2-c2c1ccc1c2c2ccccc2n1-c1nc(-c2ccc(-c3ccccc3)cc2)c2ccccc2n1 ; CC1(C)c2ccccc2-c2ccc3c(c21)c1ccccc1n3-c1nc(-c2ccc(-c3ccccc3)cc2)c2ccccc2n1]

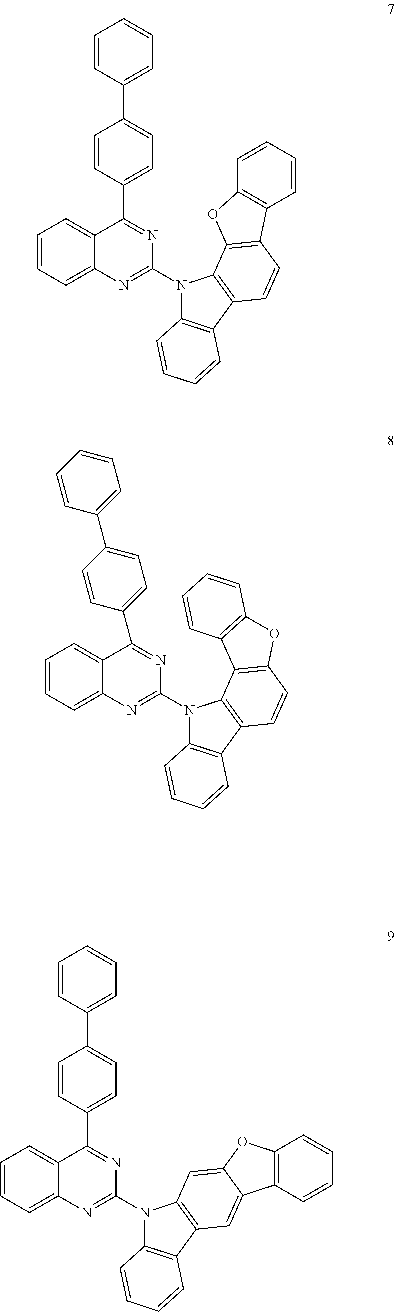 [SMILES: c1ccc(-c2ccc(-c3nc(-n4c5ccccc5c5ccc6c7ccccc7oc6c54)nc4ccccc34)cc2)cc1 ; c1ccc(-c2ccc(-c3nc(-n4c5ccccc5c5ccc6oc7ccccc7c6c54)nc4ccccc34)cc2)cc1 ; c1ccc(-c2ccc(-c3nc(-n4c5ccccc5c5cc6c(cc54)oc4ccccc46)nc4ccccc34)cc2)cc1]

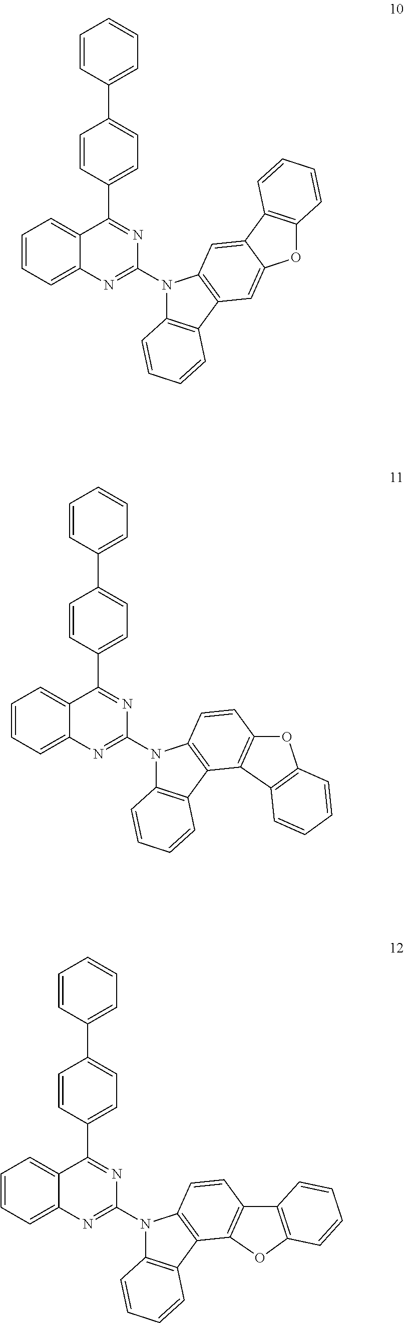 [SMILES: c1ccc(-c2ccc(-c3nc(-n4c5ccccc5c5cc6oc7ccccc7c6cc54)nc4ccccc34)cc2)cc1 ; c1ccc(-c2ccc(-c3nc(-n4c5ccccc5c5c6c(ccc54)oc4ccccc46)nc4ccccc34)cc2)cc1 ; c1ccc(-c2ccc(-c3nc(-n4c5ccccc5c5c6oc7ccccc7c6ccc54)nc4ccccc34)cc2)cc1]

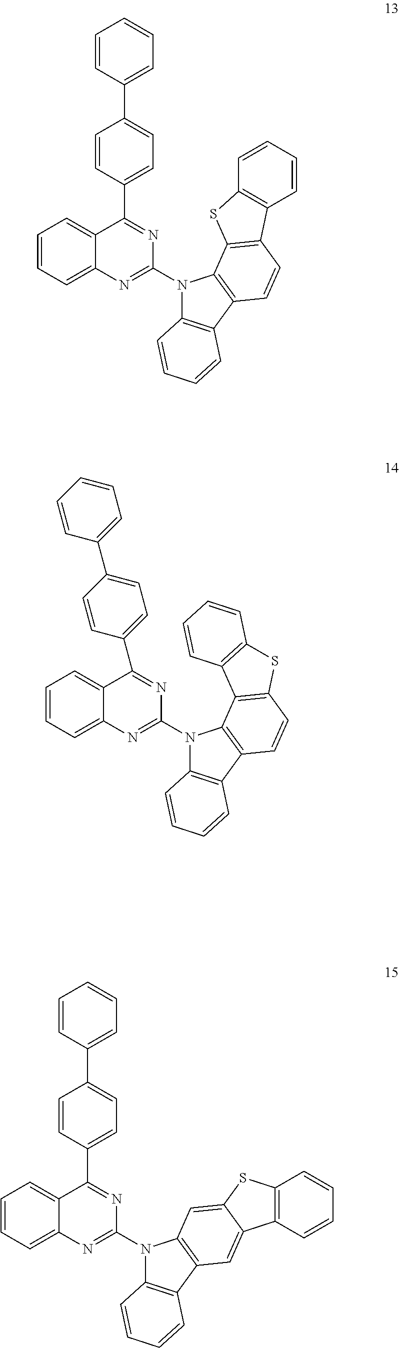 [SMILES: c1ccc(-c2ccc(-c3nc(-n4c5ccccc5c5ccc6c7ccccc7sc6c54)nc4ccccc34)cc2)cc1 ; c1ccc(-c2ccc(-c3nc(-n4c5ccccc5c5ccc6sc7ccccc7c6c54)nc4ccccc34)cc2)cc1 ; c1ccc(-c2ccc(-c3nc(-n4c5ccccc5c5cc6c(cc54)sc4ccccc46)nc4ccccc34)cc2)cc1]

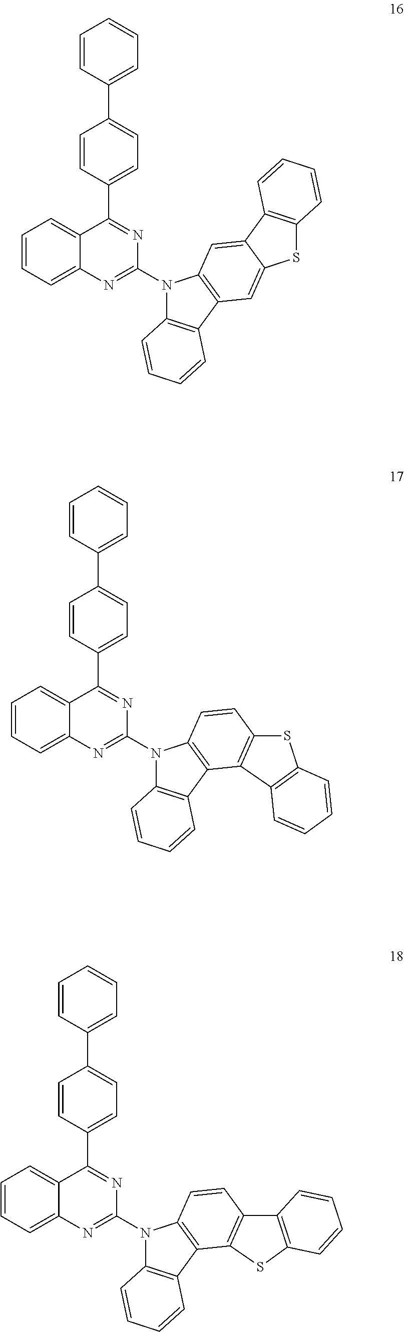 [SMILES: c1ccc(-c2ccc(-c3nc(-n4c5ccccc5c5cc6sc7ccccc7c6cc54)nc4ccccc34)cc2)cc1 ; c1ccc(-c2ccc(-c3nc(-n4c5ccccc5c5c6c(ccc54)sc4ccccc46)nc4ccccc34)cc2)cc1 ; c1ccc(-c2ccc(-c3nc(-n4c5ccccc5c5c6sc7ccccc7c6ccc54)nc4ccccc34)cc2)cc1]

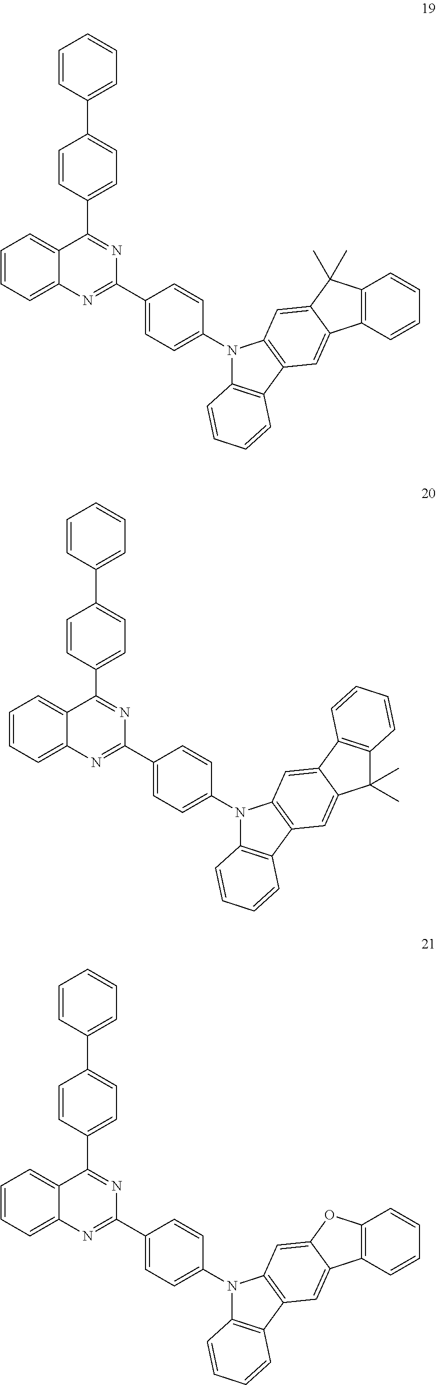 [SMILES: CC1(C)c2ccccc2-c2cc3c4ccccc4n(-c4ccc(-c5nc(-c6ccc(-c7ccccc7)cc6)c6ccccc6n5)cc4)c3cc21 ; CC1(C)c2ccccc2-c2cc3c(cc21)c1ccccc1n3-c1ccc(-c2nc(-c3ccc(-c4ccccc4)cc3)c3ccccc3n2)cc1 ; c1ccc(-c2ccc(-c3nc(-c4ccc(-n5c6ccccc6c6cc7c(cc65)oc5ccccc57)cc4)nc4ccccc34)cc2)cc1]

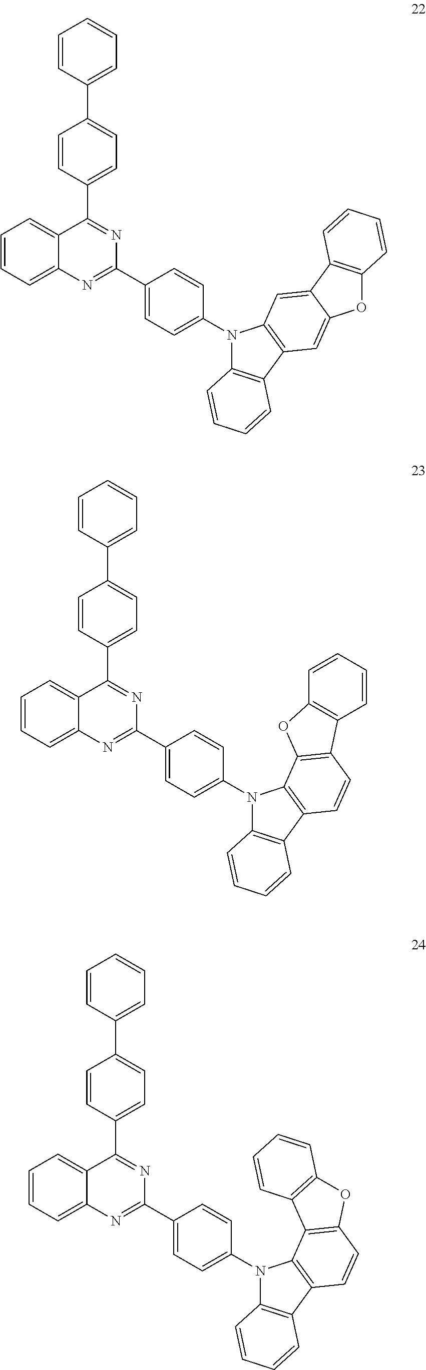 [SMILES: c1ccc(-c2ccc(-c3nc(-c4ccc(-n5c6ccccc6c6cc7oc8ccccc8c7cc65)cc4)nc4ccccc34)cc2)cc1 ; c1ccc(-c2ccc(-c3nc(-c4ccc(-n5c6ccccc6c6ccc7c8ccccc8oc7c65)cc4)nc4ccccc34)cc2)cc1 ; c1ccc(-c2ccc(-c3nc(-c4ccc(-n5c6ccccc6c6ccc7oc8ccccc8c7c65)cc4)nc4ccccc34)cc2)cc1]

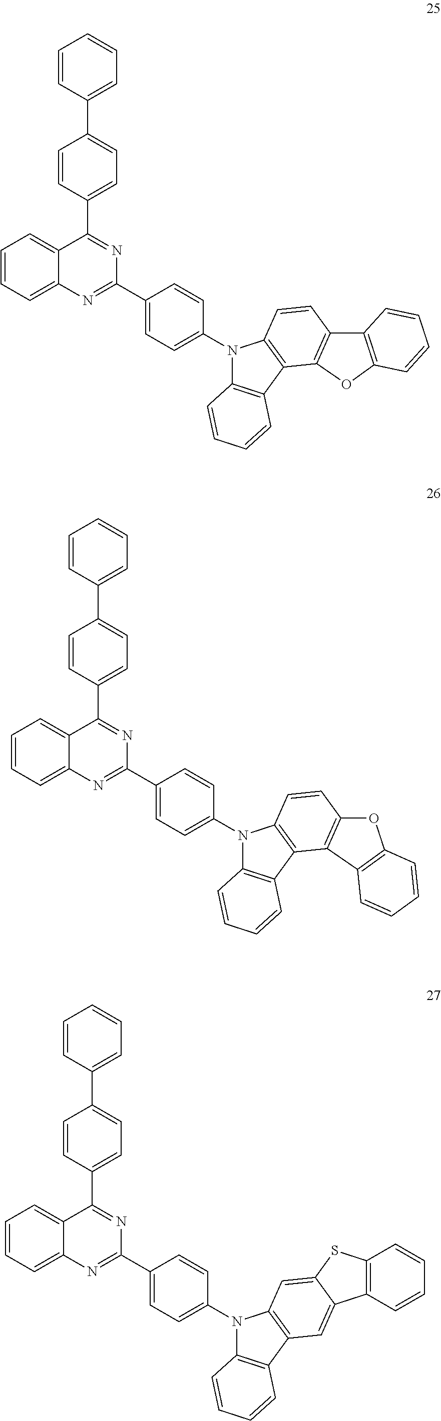 [SMILES: c1ccc(-c2ccc(-c3nc(-c4ccc(-n5c6ccccc6c6c7oc8ccccc8c7ccc65)cc4)nc4ccccc34)cc2)cc1 ; c1ccc(-c2ccc(-c3nc(-c4ccc(-n5c6ccccc6c6c7c(ccc65)oc5ccccc57)cc4)nc4ccccc34)cc2)cc1 ; c1ccc(-c2ccc(-c3nc(-c4ccc(-n5c6ccccc6c6cc7c(cc65)sc5ccccc57)cc4)nc4ccccc34)cc2)cc1]

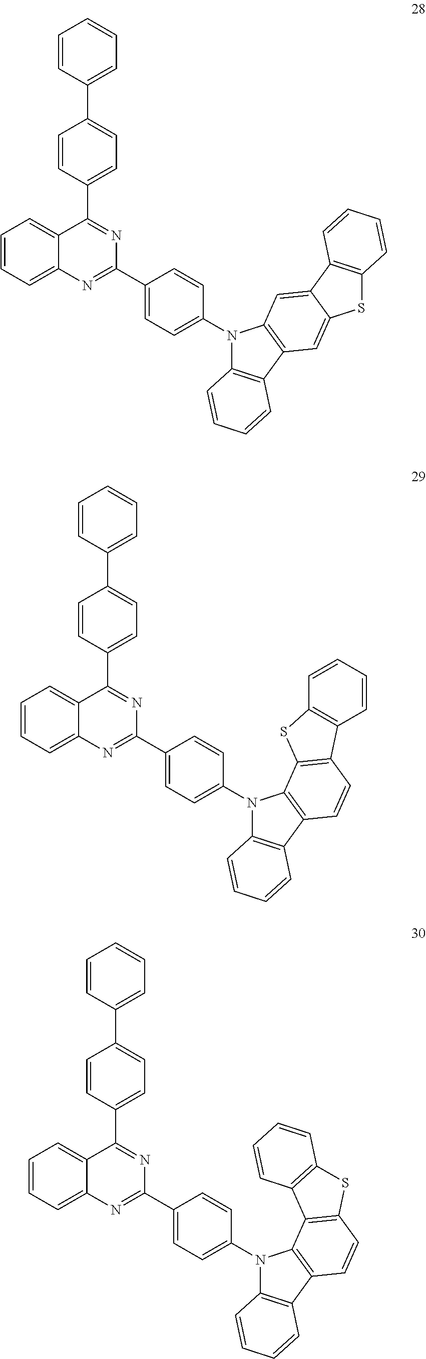 [SMILES: c1ccc(-c2ccc(-c3nc(-c4ccc(-n5c6ccccc6c6cc7sc8ccccc8c7cc65)cc4)nc4ccccc34)cc2)cc1 ; c1ccc(-c2ccc(-c3nc(-c4ccc(-n5c6ccccc6c6ccc7c8ccccc8sc7c65)cc4)nc4ccccc34)cc2)cc1 ; c1ccc(-c2ccc(-c3nc(-c4ccc(-n5c6ccccc6c6ccc7sc8ccccc8c7c65)cc4)nc4ccccc34)cc2)cc1]

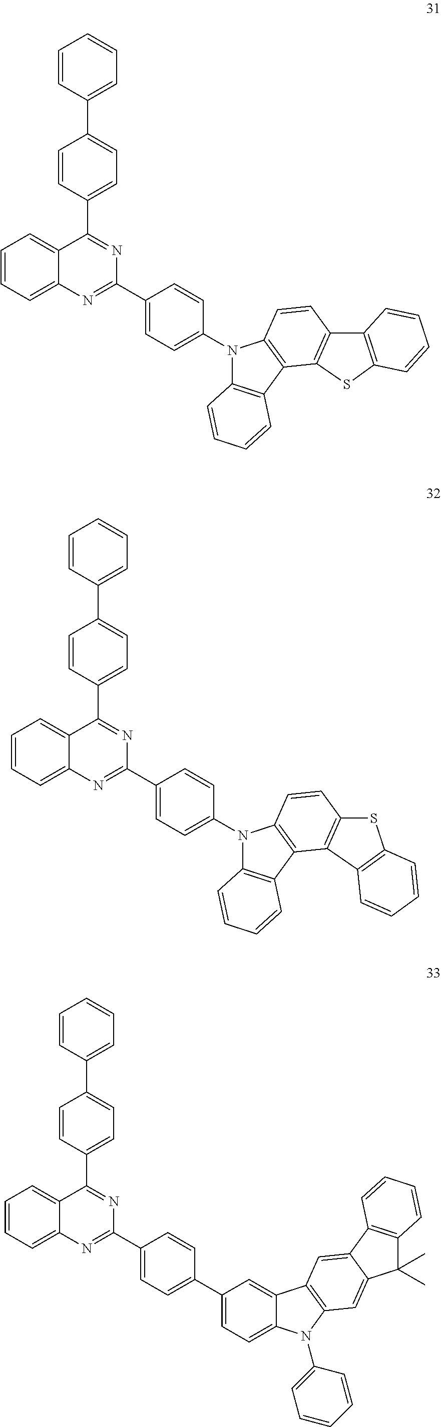 [SMILES: c1ccc(-c2ccc(-c3nc(-c4ccc(-n5c6ccccc6c6c7sc8ccccc8c7ccc65)cc4)nc4ccccc34)cc2)cc1 ; c1ccc(-c2ccc(-c3nc(-c4ccc(-n5c6ccccc6c6c7c(ccc65)sc5ccccc57)cc4)nc4ccccc34)cc2)cc1 ; CC1(C)c2ccccc2-c2cc3c4cc(-c5ccc(-c6nc(-c7ccc(-c8ccccc8)cc7)c7ccccc7n6)cc5)ccc4n(-c4ccccc4)c3cc21]

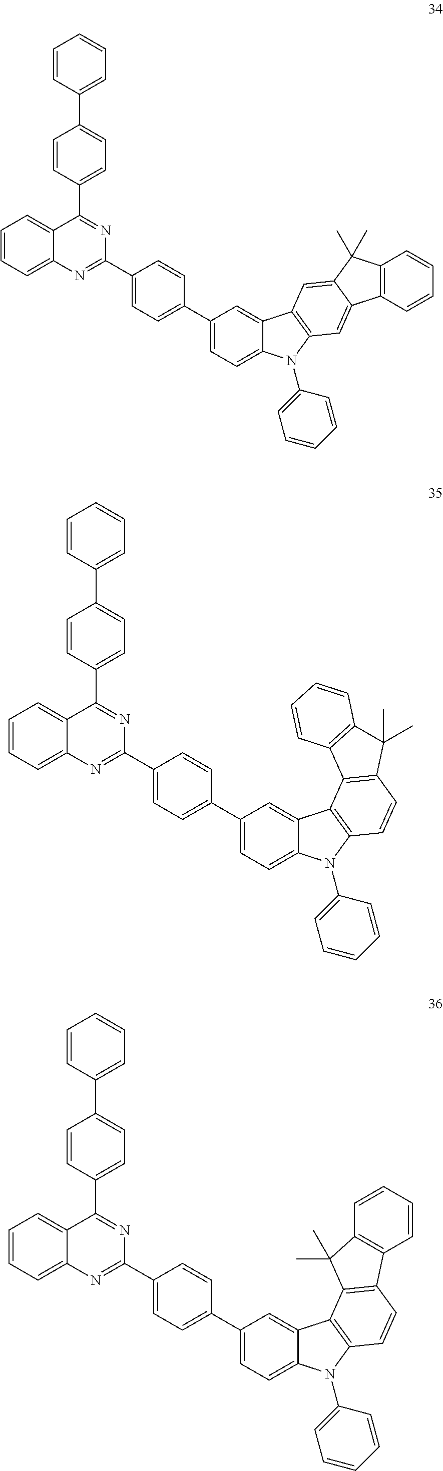 [SMILES: CC1(C)c2ccccc2-c2cc3c(cc21)c1cc(-c2ccc(-c4nc(-c5ccc(-c6ccccc6)cc5)c5ccccc5n4)cc2)ccc1n3-c1ccccc1 ; CC1(C)c2ccccc2-c2c1ccc1c2c2cc(-c3ccc(-c4nc(-c5ccc(-c6ccccc6)cc5)c5ccccc5n4)cc3)ccc2n1-c1ccccc1 ; CC1(C)c2ccccc2-c2ccc3c(c21)c1cc(-c2ccc(-c4nc(-c5ccc(-c6ccccc6)cc5)c5ccccc5n4)cc2)ccc1n3-c1ccccc1]

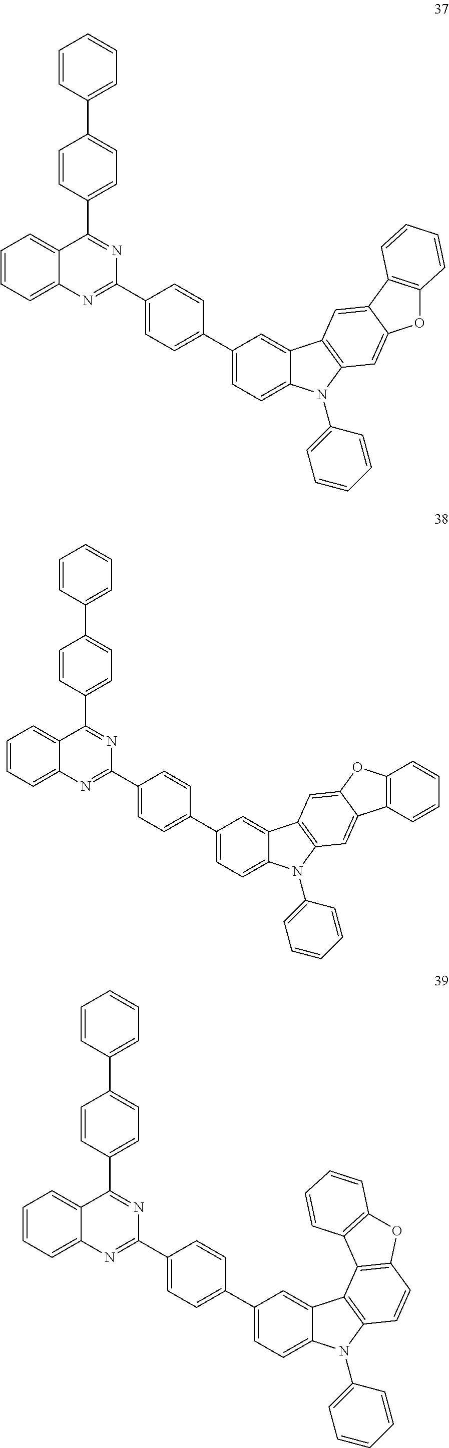 [SMILES: c1ccc(-c2ccc(-c3nc(-c4ccc(-c5ccc6c(c5)c5cc7c(cc5n6-c5ccccc5)oc5ccccc57)cc4)nc4ccccc34)cc2)cc1 ; c1ccc(-c2ccc(-c3nc(-c4ccc(-c5ccc6c(c5)c5cc7oc8ccccc8c7cc5n6-c5ccccc5)cc4)nc4ccccc34)cc2)cc1 ; c1ccc(-c2ccc(-c3nc(-c4ccc(-c5ccc6c(c5)c5c7c(ccc5n6-c5ccccc5)oc5ccccc57)cc4)nc4ccccc34)cc2)cc1]

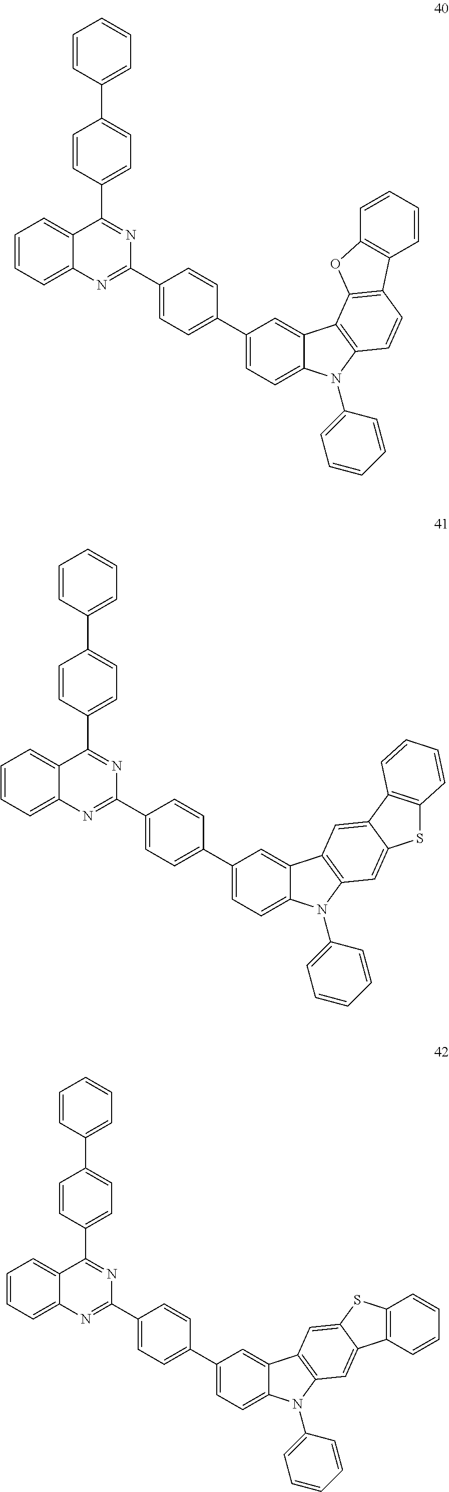 [SMILES: c1ccc(-c2ccc(-c3nc(-c4ccc(-c5ccc6c(c5)c5c7oc8ccccc8c7ccc5n6-c5ccccc5)cc4)nc4ccccc34)cc2)cc1 ; c1ccc(-c2ccc(-c3nc(-c4ccc(-c5ccc6c(c5)c5cc7c(cc5n6-c5ccccc5)sc5ccccc57)cc4)nc4ccccc34)cc2)cc1 ; c1ccc(-c2ccc(-c3nc(-c4ccc(-c5ccc6c(c5)c5cc7sc8ccccc8c7cc5n6-c5ccccc5)cc4)nc4ccccc34)cc2)cc1]

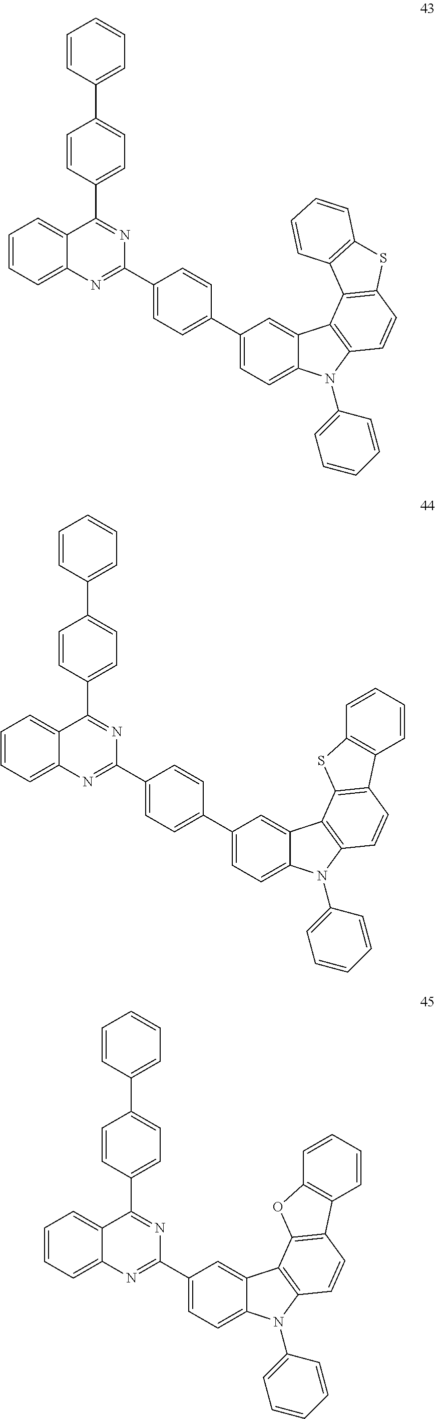 [SMILES: c1ccc(-c2ccc(-c3nc(-c4ccc(-c5ccc6c(c5)c5c7c(ccc5n6-c5ccccc5)sc5ccccc57)cc4)nc4ccccc34)cc2)cc1 ; c1ccc(-c2ccc(-c3nc(-c4ccc(-c5ccc6c(c5)c5c7sc8ccccc8c7ccc5n6-c5ccccc5)cc4)nc4ccccc34)cc2)cc1 ; c1ccc(-c2ccc(-c3nc(-c4ccc5c(c4)c4c6oc7ccccc7c6ccc4n5-c4ccccc4)nc4ccccc34)cc2)cc1]

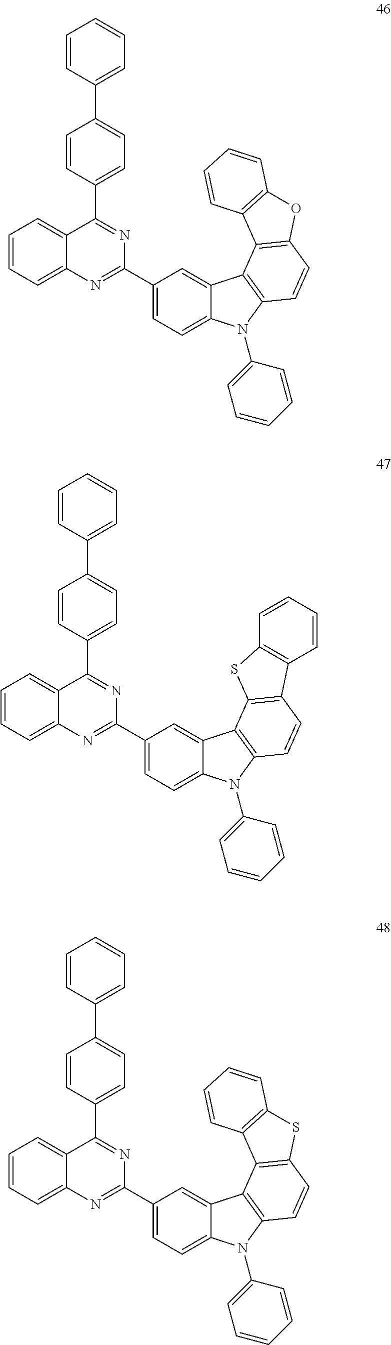 [SMILES: c1ccc(-c2ccc(-c3nc(-c4ccc5c(c4)c4c6c(ccc4n5-c4ccccc4)oc4ccccc46)nc4ccccc34)cc2)cc1 ; c1ccc(-c2ccc(-c3nc(-c4ccc5c(c4)c4c6sc7ccccc7c6ccc4n5-c4ccccc4)nc4ccccc34)cc2)cc1 ; c1ccc(-c2ccc(-c3nc(-c4ccc5c(c4)c4c6c(ccc4n5-c4ccccc4)sc4ccccc46)nc4ccccc34)cc2)cc1]

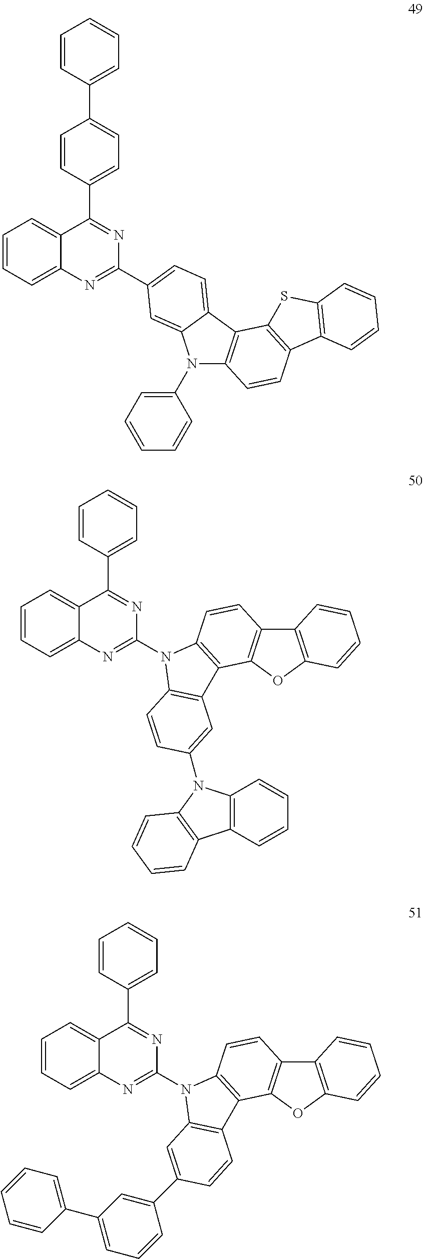 [SMILES: c1ccc(-c2ccc(-c3nc(-c4ccc5c6c7sc8ccccc8c7ccc6n(-c6ccccc6)c5c4)nc4ccccc34)cc2)cc1 ; c1ccc(-c2nc(-n3c4ccc(-n5c6ccccc6c6ccccc65)cc4c4c5oc6ccccc6c5ccc43)nc3ccccc23)cc1 ; c1ccc(-c2cccc(-c3ccc4c5c6oc7ccccc7c6ccc5n(-c5nc(-c6ccccc6)c6ccccc6n5)c4c3)c2)cc1]

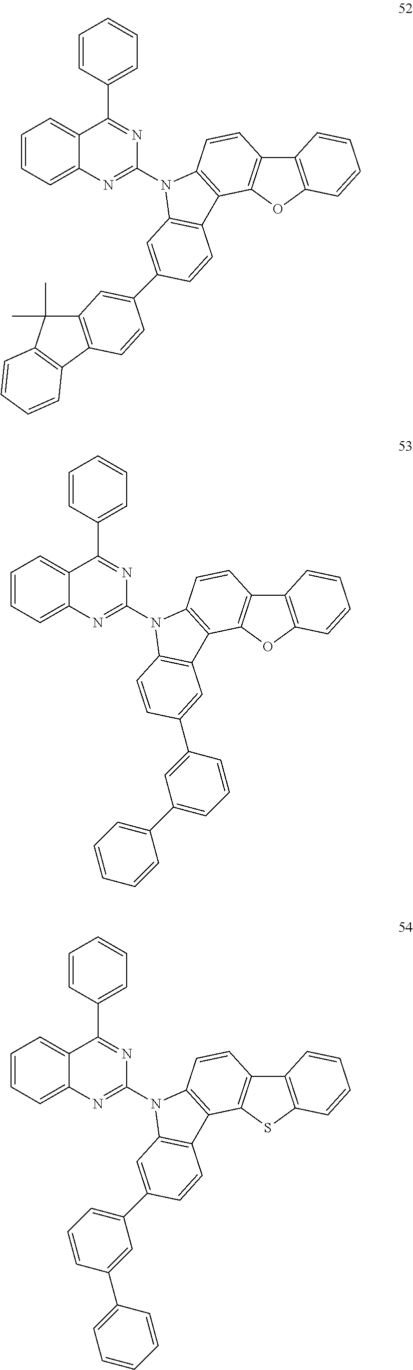 [SMILES: CC1(C)c2ccccc2-c2ccc(-c3ccc4c5c6oc7ccccc7c6ccc5n(-c5nc(-c6ccccc6)c6ccccc6n5)c4c3)cc21 ; c1ccc(-c2cccc(-c3ccc4c(c3)c3c5oc6ccccc6c5ccc3n4-c3nc(-c4ccccc4)c4ccccc4n3)c2)cc1 ; c1ccc(-c2cccc(-c3ccc4c5c6sc7ccccc7c6ccc5n(-c5nc(-c6ccccc6)c6ccccc6n5)c4c3)c2)cc1]

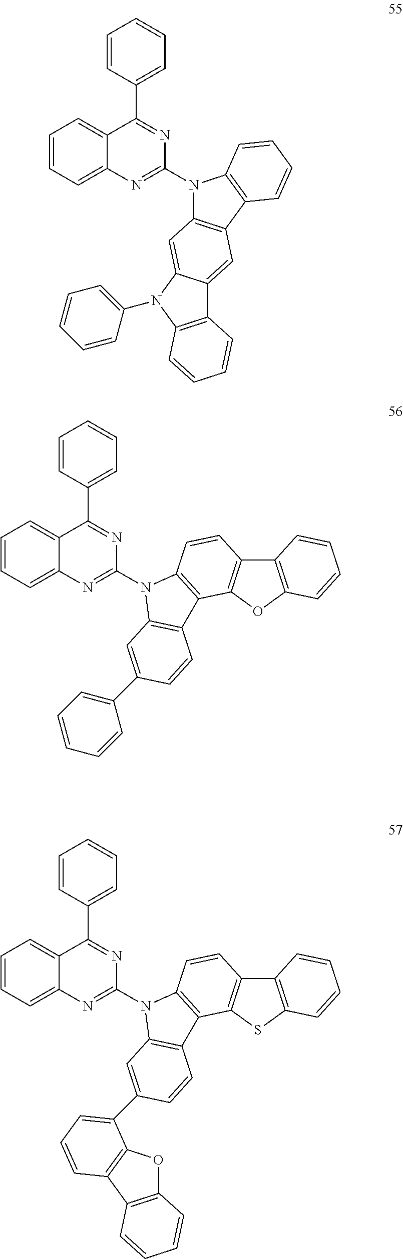 [SMILES: c1ccc(-c2nc(-n3c4ccccc4c4cc5c6ccccc6n(-c6ccccc6)c5cc43)nc3ccccc23)cc1 ; c1ccc(-c2ccc3c4c5oc6ccccc6c5ccc4n(-c4nc(-c5ccccc5)c5ccccc5n4)c3c2)cc1 ; c1ccc(-c2nc(-n3c4cc(-c5cccc6c5oc5ccccc56)ccc4c4c5sc6ccccc6c5ccc43)nc3ccccc23)cc1]

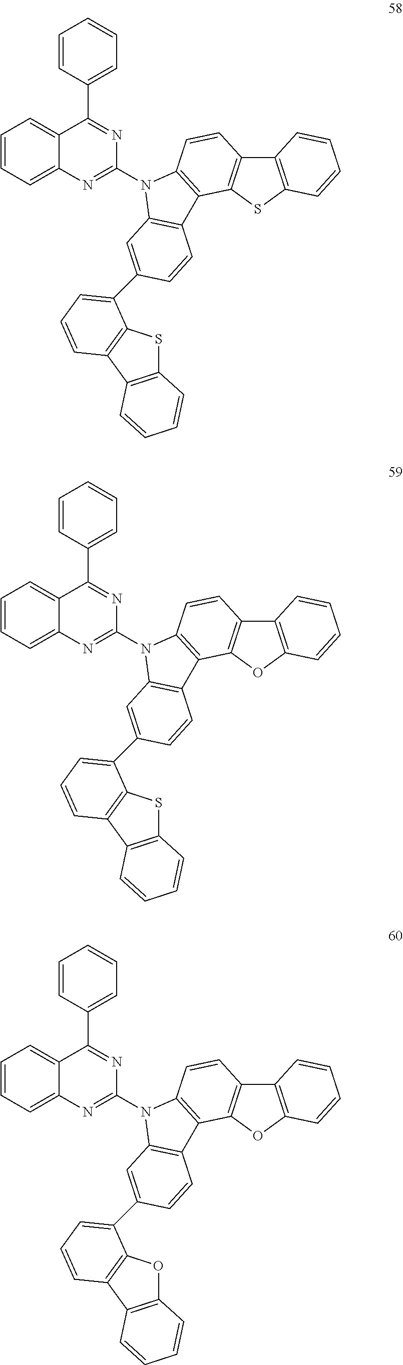 [SMILES: c1ccc(-c2nc(-n3c4cc(-c5cccc6c5sc5ccccc56)ccc4c4c5sc6ccccc6c5ccc43)nc3ccccc23)cc1 ; c1ccc(-c2nc(-n3c4cc(-c5cccc6c5sc5ccccc56)ccc4c4c5oc6ccccc6c5ccc43)nc3ccccc23)cc1 ; c1ccc(-c2nc(-n3c4cc(-c5cccc6c5oc5ccccc56)ccc4c4c5oc6ccccc6c5ccc43)nc3ccccc23)cc1]

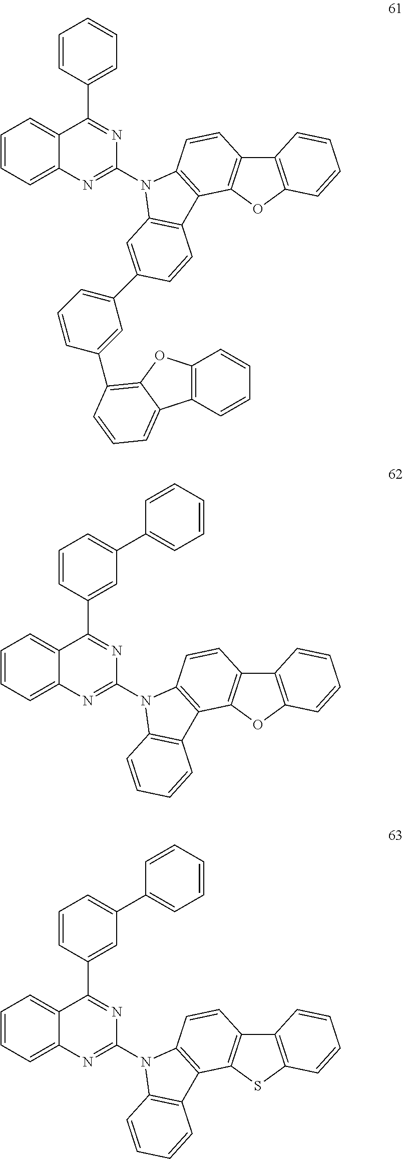 [SMILES: c1ccc(-c2nc(-n3c4cc(-c5cccc(-c6cccc7c6oc6ccccc67)c5)ccc4c4c5oc6ccccc6c5ccc43)nc3ccccc23)cc1 ; c1ccc(-c2cccc(-c3nc(-n4c5ccccc5c5c6oc7ccccc7c6ccc54)nc4ccccc34)c2)cc1 ; c1ccc(-c2cccc(-c3nc(-n4c5ccccc5c5c6sc7ccccc7c6ccc54)nc4ccccc34)c2)cc1]

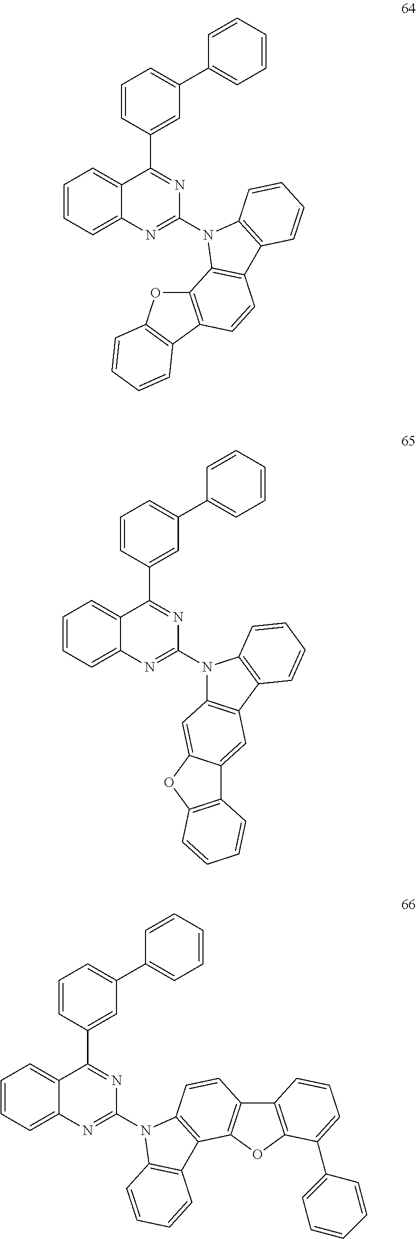 [SMILES: c1ccc(-c2cccc(-c3nc(-n4c5ccccc5c5ccc6c7ccccc7oc6c54)nc4ccccc34)c2)cc1 ; c1ccc(-c2cccc(-c3nc(-n4c5ccccc5c5cc6c(cc54)oc4ccccc46)nc4ccccc34)c2)cc1 ; c1ccc(-c2cccc(-c3nc(-n4c5ccccc5c5c6oc7c(-c8ccccc8)cccc7c6ccc54)nc4ccccc34)c2)cc1]

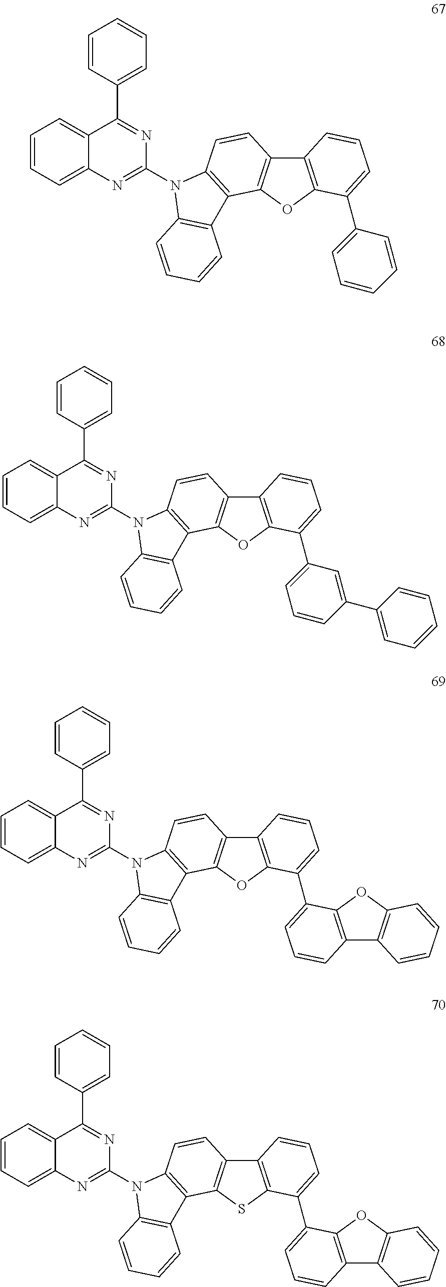 [SMILES: c1ccc(-c2nc(-n3c4ccccc4c4c5oc6c(-c7ccccc7)cccc6c5ccc43)nc3ccccc23)cc1 ; c1ccc(-c2cccc(-c3cccc4c3oc3c4ccc4c3c3ccccc3n4-c3nc(-c4ccccc4)c4ccccc4n3)c2)cc1 ; c1ccc(-c2nc(-n3c4ccccc4c4c5oc6c(-c7cccc8c7oc7ccccc78)cccc6c5ccc43)nc3ccccc23)cc1 ; c1ccc(-c2nc(-n3c4ccccc4c4c5sc6c(-c7cccc8c7oc7ccccc78)cccc6c5ccc43)nc3ccccc23)cc1]

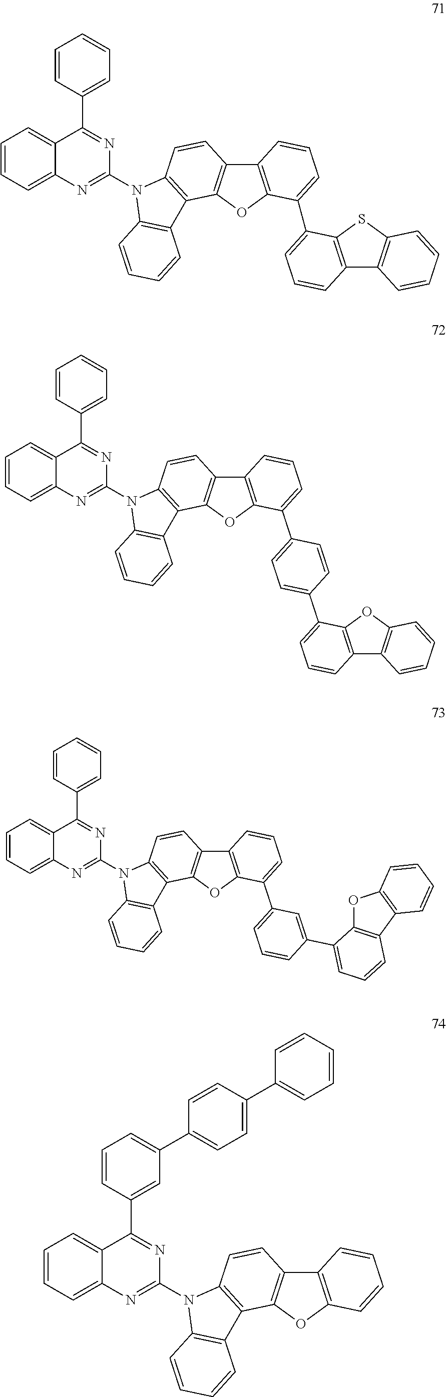 [SMILES: c1ccc(-c2nc(-n3c4ccccc4c4c5oc6c(-c7cccc8c7sc7ccccc78)cccc6c5ccc43)nc3ccccc23)cc1 ; c1ccc(-c2nc(-n3c4ccccc4c4c5oc6c(-c7ccc(-c8cccc9c8oc8ccccc89)cc7)cccc6c5ccc43)nc3ccccc23)cc1 ; c1ccc(-c2nc(-n3c4ccccc4c4c5oc6c(-c7cccc(-c8cccc9c8oc8ccccc89)c7)cccc6c5ccc43)nc3ccccc23)cc1 ; c1ccc(-c2ccc(-c3cccc(-c4nc(-n5c6ccccc6c6c7oc8ccccc8c7ccc65)nc5ccccc45)c3)cc2)cc1]

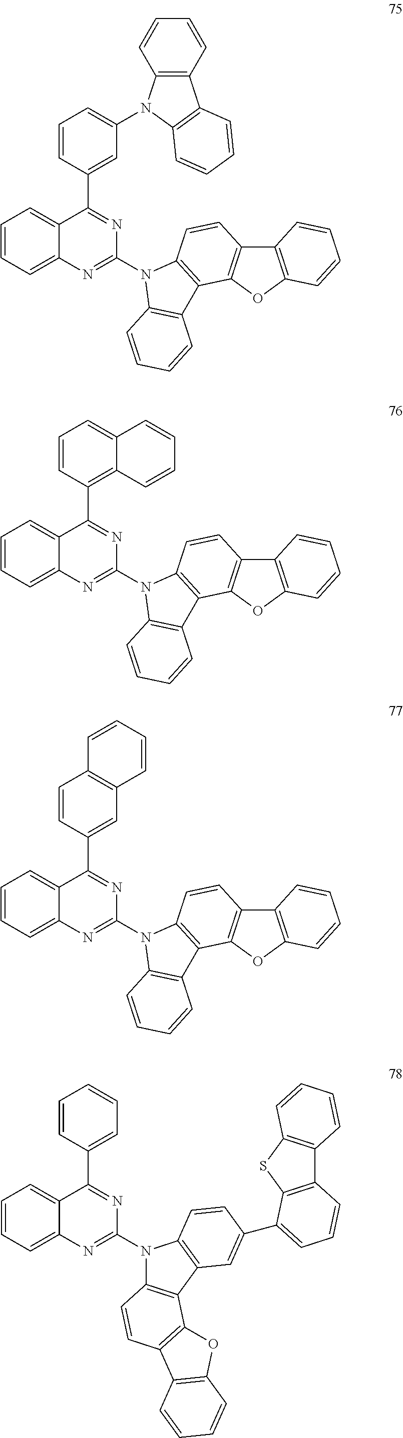 [SMILES: c1cc(-c2nc(-n3c4ccccc4c4c5oc6ccccc6c5ccc43)nc3ccccc23)cc(-n2c3ccccc3c3ccccc32)c1 ; c1ccc2c(-c3nc(-n4c5ccccc5c5c6oc7ccccc7c6ccc54)nc4ccccc34)cccc2c1 ; c1ccc2cc(-c3nc(-n4c5ccccc5c5c6oc7ccccc7c6ccc54)nc4ccccc34)ccc2c1 ; c1ccc(-c2nc(-n3c4ccc(-c5cccc6c5sc5ccccc56)cc4c4c5oc6ccccc6c5ccc43)nc3ccccc23)cc1]

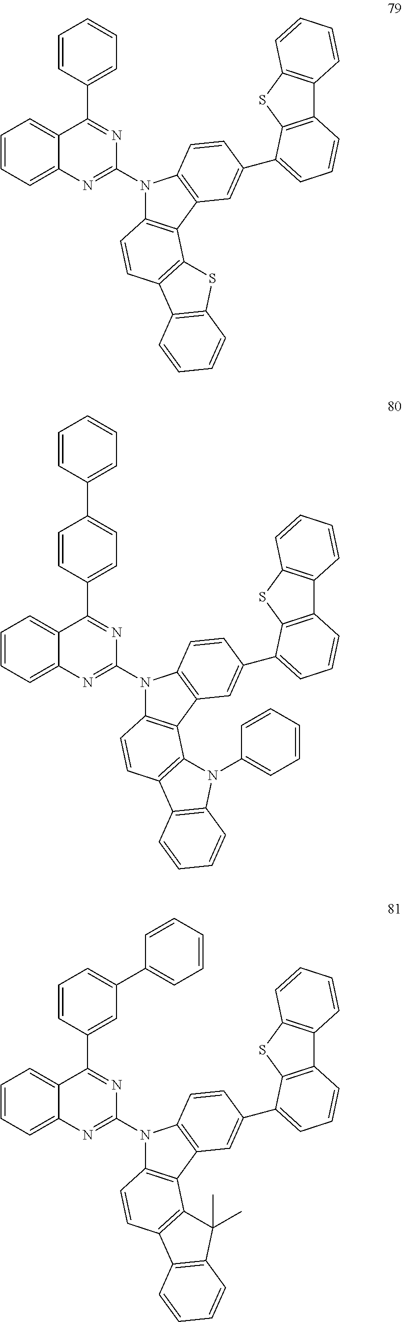 [SMILES: c1ccc(-c2nc(-n3c4ccc(-c5cccc6c5sc5ccccc56)cc4c4c5sc6ccccc6c5ccc43)nc3ccccc23)cc1 ; c1ccc(-c2ccc(-c3nc(-n4c5ccc(-c6cccc7c6sc6ccccc67)cc5c5c4ccc4c6ccccc6n(-c6ccccc6)c45)nc4ccccc34)cc2)cc1 ; CC1(C)c2ccccc2-c2ccc3c(c21)c1cc(-c2cccc4c2sc2ccccc24)ccc1n3-c1nc(-c2cccc(-c3ccccc3)c2)c2ccccc2n1]

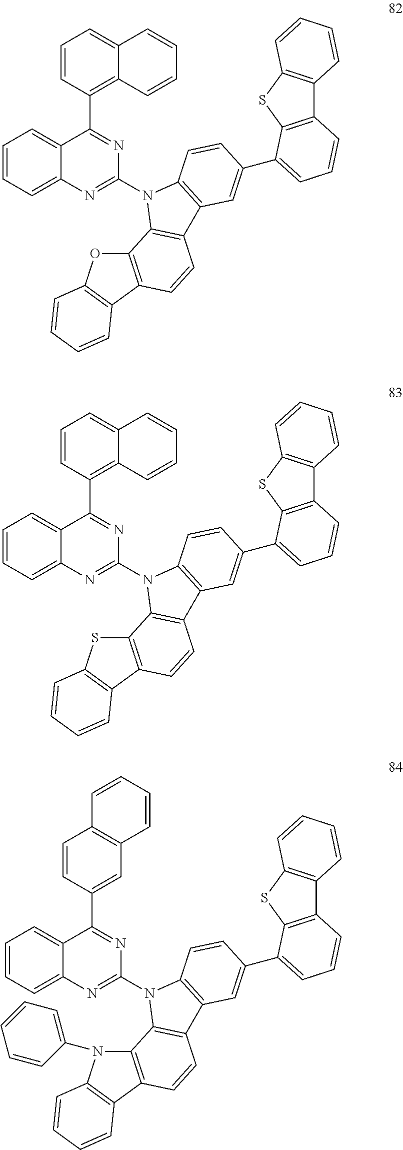 [SMILES: c1ccc2c(-c3nc(-n4c5ccc(-c6cccc7c6sc6ccccc67)cc5c5ccc6c7ccccc7oc6c54)nc4ccccc34)cccc2c1 ; c1ccc2c(-c3nc(-n4c5ccc(-c6cccc7c6sc6ccccc67)cc5c5ccc6c7ccccc7sc6c54)nc4ccccc34)cccc2c1 ; c1ccc(-n2c3ccccc3c3ccc4c5cc(-c6cccc7c6sc6ccccc67)ccc5n(-c5nc(-c6ccc7ccccc7c6)c6ccccc6n5)c4c32)cc1]

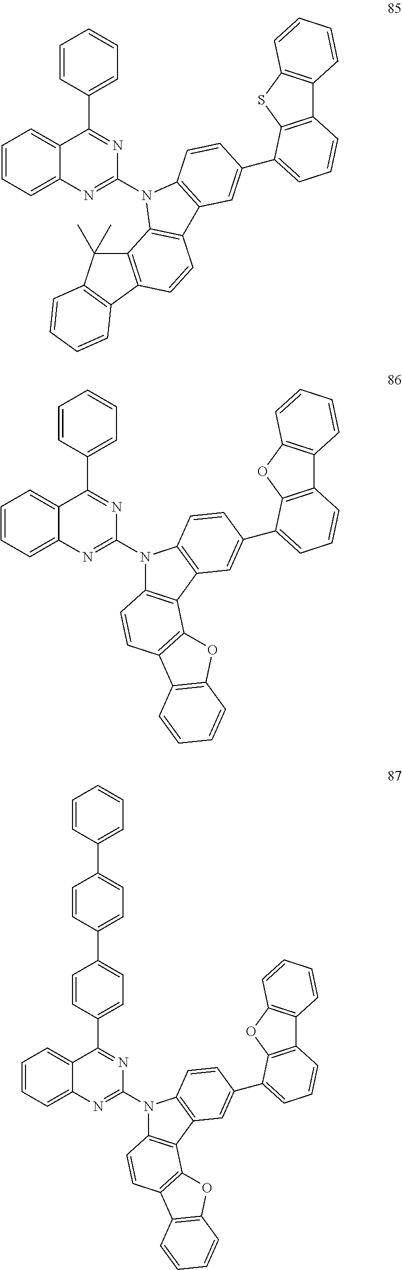

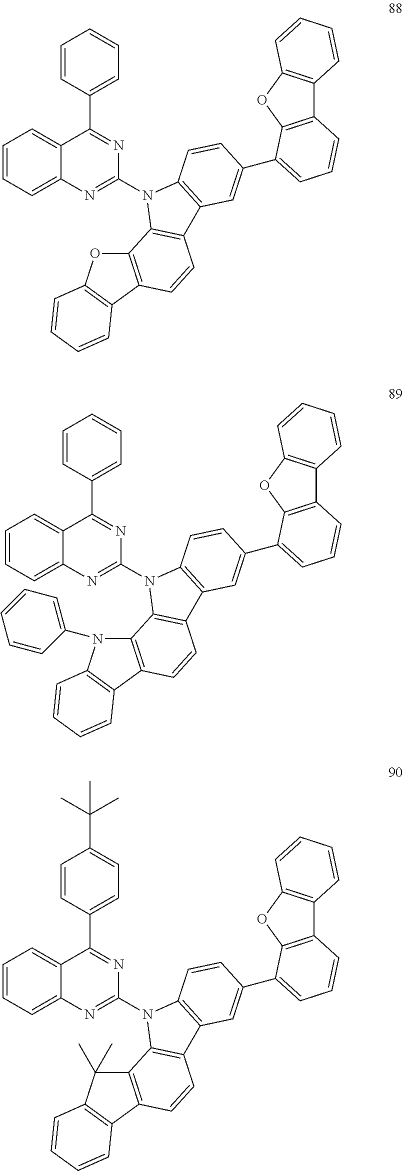

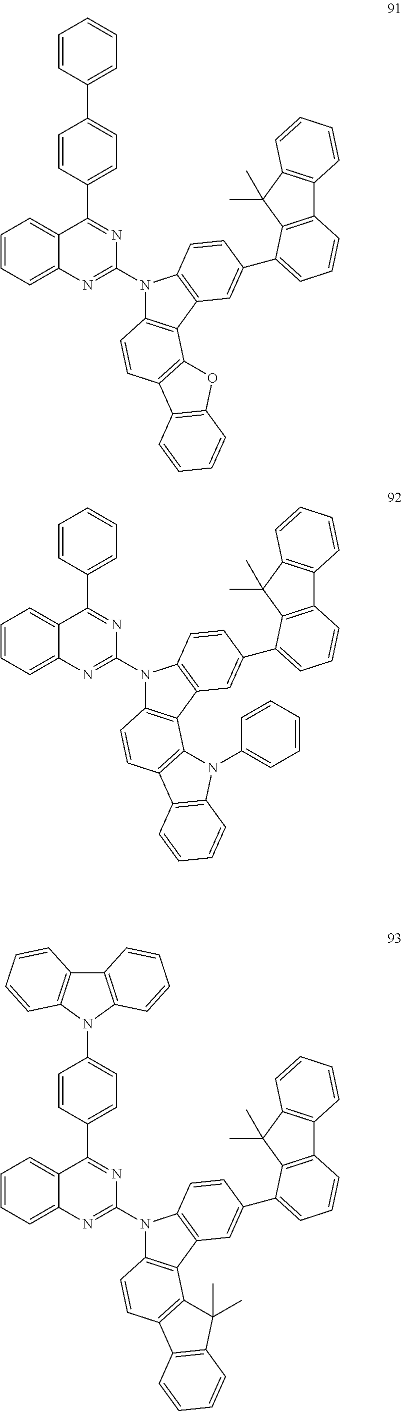 [SMILES: CC1(C)c2ccccc2-c2cccc(-c3ccc4c(c3)c3c5oc6ccccc6c5ccc3n4-c3nc(-c4ccc(-c5ccccc5)cc4)c4ccccc4n3)c21 ; CC1(C)c2ccccc2-c2cccc(-c3ccc4c(c3)c3c(ccc5c6ccccc6n(-c6ccccc6)c53)n4-c3nc(-c4ccccc4)c4ccccc4n3)c21 ; CC1(C)c2ccccc2-c2cccc(-c3ccc4c(c3)c3c5c(ccc3n4-c3nc(-c4ccc(-n6c7ccccc7c7ccccc76)cc4)c4ccccc4n3)-c3ccccc3C5(C)C)c21]

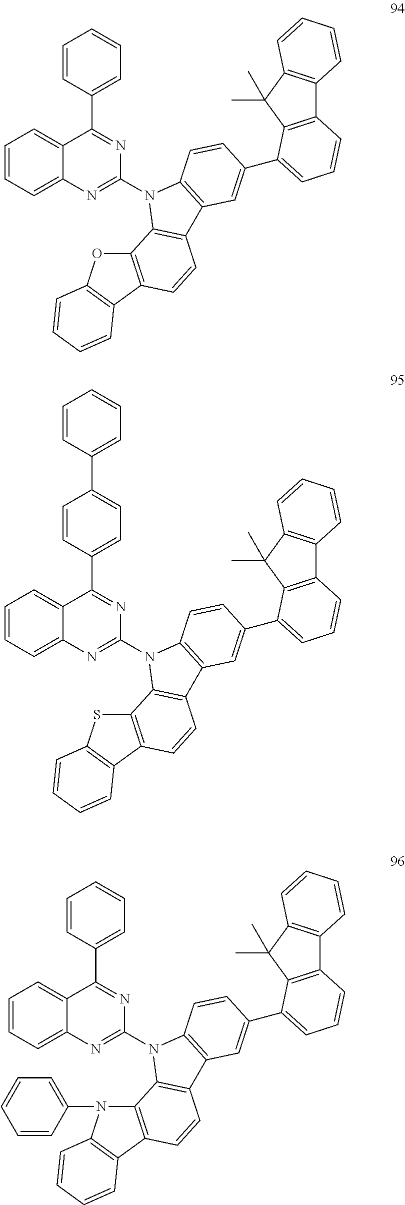

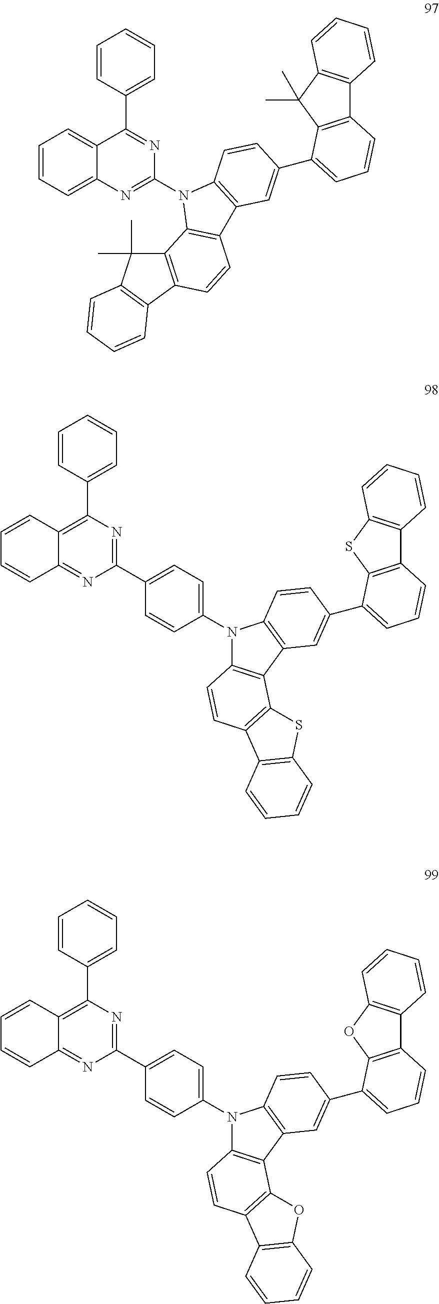 [SMILES: CC1(C)c2ccccc2-c2cccc(-c3ccc4c(c3)c3ccc5c(c3n4-c3nc(-c4ccccc4)c4ccccc4n3)C(C)(C)c3ccccc3-5)c21 ; c1ccc(-c2nc(-c3ccc(-n4c5ccc(-c6cccc7c6sc6ccccc67)cc5c5c6sc7ccccc7c6ccc54)cc3)nc3ccccc23)cc1 ; c1ccc(-c2nc(-c3ccc(-n4c5ccc(-c6cccc7c6oc6ccccc67)cc5c5c6oc7ccccc7c6ccc54)cc3)nc3ccccc23)cc1]

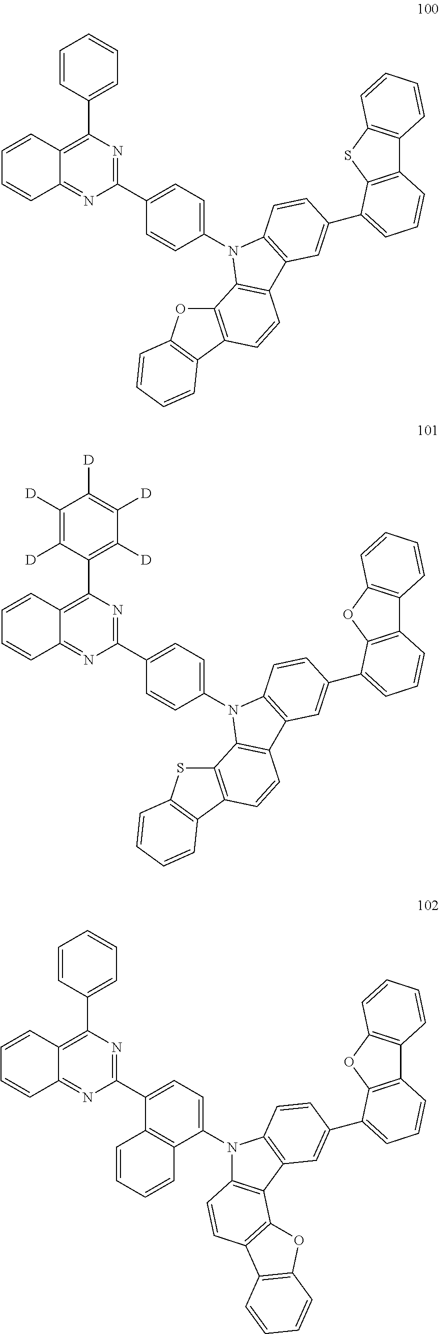 [SMILES: c1ccc(-c2nc(-c3ccc(-n4c5ccc(-c6cccc7c6sc6ccccc67)cc5c5ccc6c7ccccc7oc6c54)cc3)nc3ccccc23)cc1 ; [2H]c1c([2H])c([2H])c(-c2nc(-c3ccc(-n4c5ccc(-c6cccc7c6oc6ccccc67)cc5c5ccc6c7ccccc7sc6c54)cc3)nc3ccccc23)c([2H])c1[2H] ; c1ccc(-c2nc(-c3ccc(-n4c5ccc(-c6cccc7c6oc6ccccc67)cc5c5c6oc7ccccc7c6ccc54)c4ccccc34)nc3ccccc23)cc1]

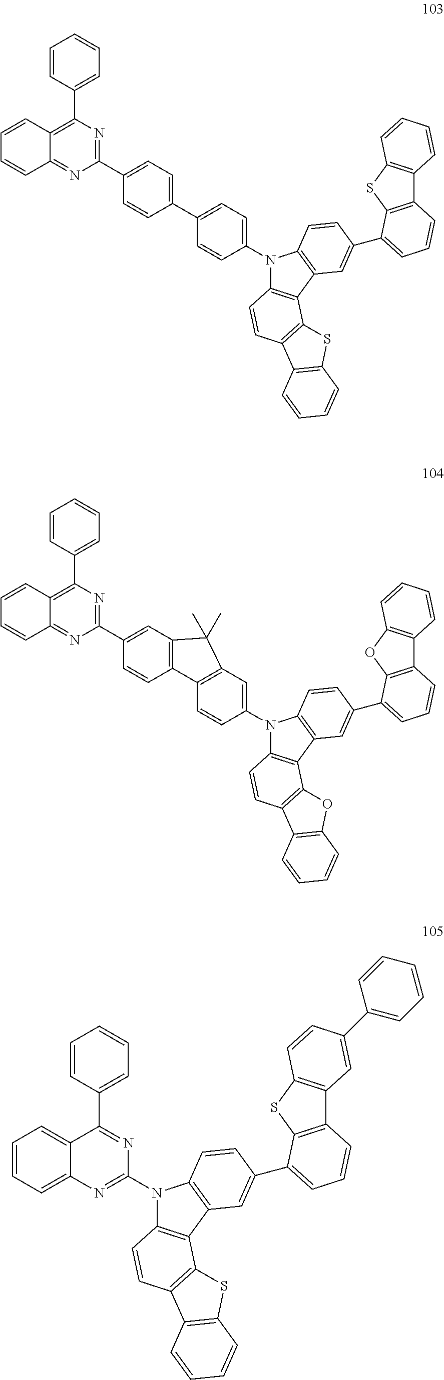 [SMILES: c1ccc(-c2nc(-c3ccc(-c4ccc(-n5c6ccc(-c7cccc8c7sc7ccccc78)cc6c6c7sc8ccccc8c7ccc65)cc4)cc3)nc3ccccc23)cc1 ; CC1(C)c2cc(-c3nc(-c4ccccc4)c4ccccc4n3)ccc2-c2ccc(-n3c4ccc(-c5cccc6c5oc5ccccc56)cc4c4c5oc6ccccc6c5ccc43)cc21 ; c1ccc(-c2ccc3sc4c(-c5ccc6c(c5)c5c7sc8ccccc8c7ccc5n6-c5nc(-c6ccccc6)c6ccccc6n5)cccc4c3c2)cc1]

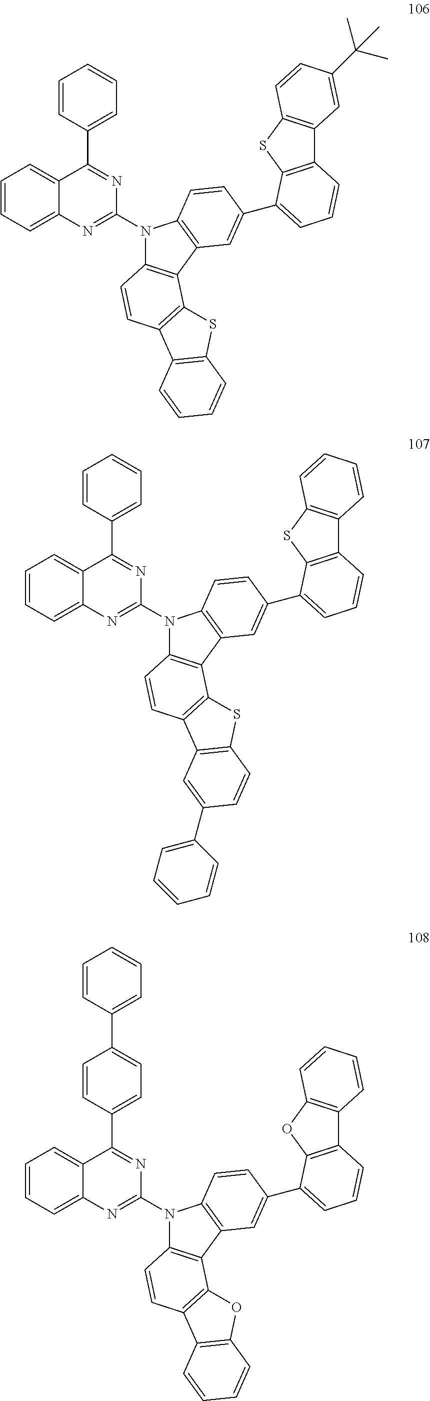 [SMILES: CC(C)(C)c1ccc2sc3c(-c4ccc5c(c4)c4c6sc7ccccc7c6ccc4n5-c4nc(-c5ccccc5)c5ccccc5n4)cccc3c2c1 ; c1ccc(-c2ccc3sc4c(ccc5c4c4cc(-c6cccc7c6sc6ccccc67)ccc4n5-c4nc(-c5ccccc5)c5ccccc5n4)c3c2)cc1 ; c1ccc(-c2ccc(-c3nc(-n4c5ccc(-c6cccc7c6oc6ccccc67)cc5c5c6oc7ccccc7c6ccc54)nc4ccccc34)cc2)cc1]

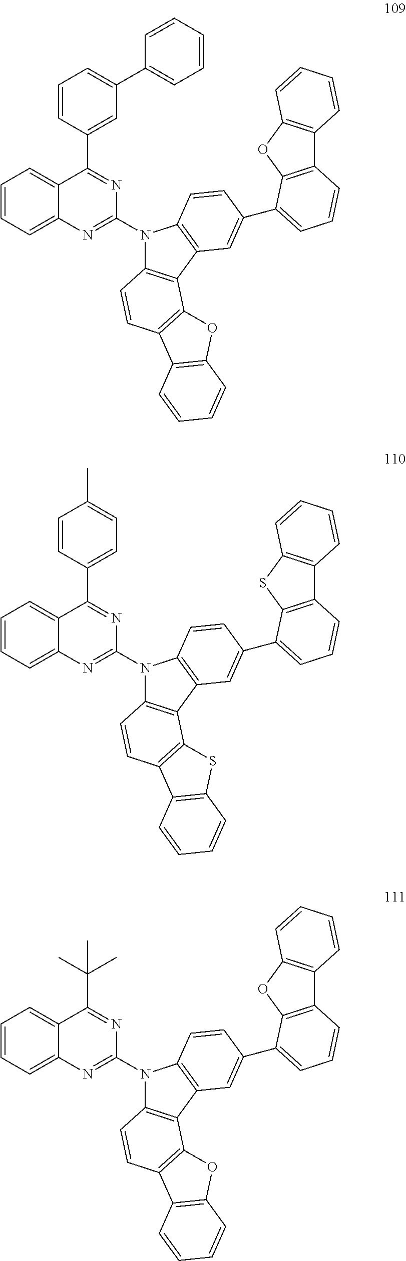 [SMILES: c1ccc(-c2cccc(-c3nc(-n4c5ccc(-c6cccc7c6oc6ccccc67)cc5c5c6oc7ccccc7c6ccc54)nc4ccccc34)c2)cc1 ; Cc1ccc(-c2nc(-n3c4ccc(-c5cccc6c5sc5ccccc56)cc4c4c5sc6ccccc6c5ccc43)nc3ccccc23)cc1 ; CC(C)(C)c1nc(-n2c3ccc(-c4cccc5c4oc4ccccc45)cc3c3c4oc5ccccc5c4ccc32)nc2ccccc12]

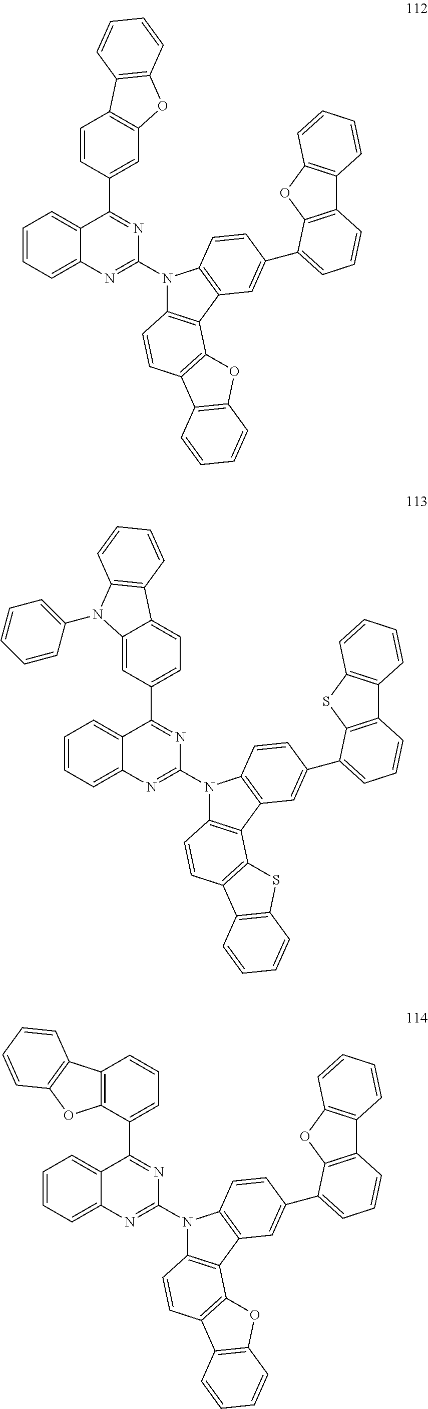 [SMILES: c1ccc2c(-c3ccc4c(c3)oc3ccccc34)nc(-n3c4ccc(-c5cccc6c5oc5ccccc56)cc4c4c5oc6ccccc6c5ccc43)nc2c1 ; c1ccc(-n2c3ccccc3c3ccc(-c4nc(-n5c6ccc(-c7cccc8c7sc7ccccc78)cc6c6c7sc8ccccc8c7ccc65)nc5ccccc45)cc32)cc1 ; c1ccc2c(-c3cccc4c3oc3ccccc34)nc(-n3c4ccc(-c5cccc6c5oc5ccccc56)cc4c4c5oc6ccccc6c5ccc43)nc2c1]

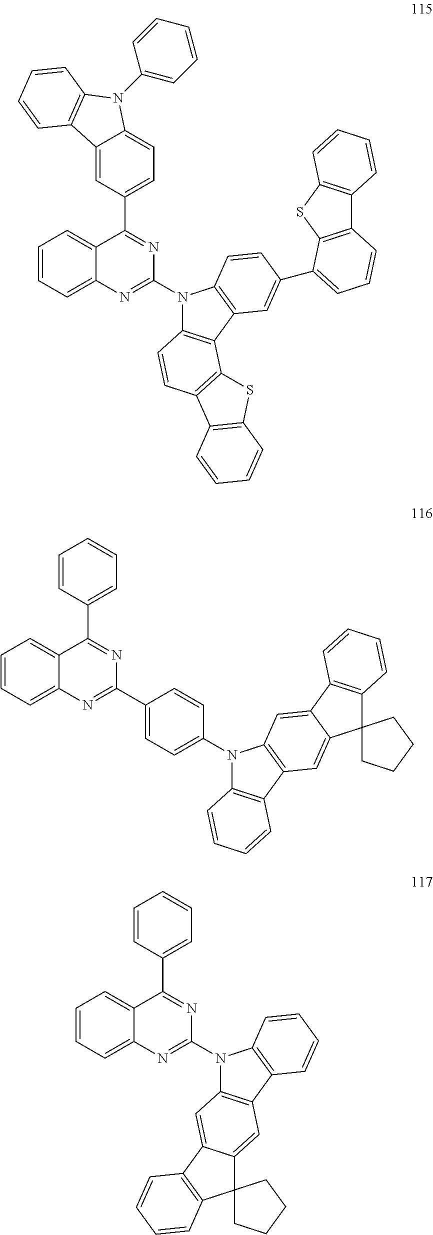 [SMILES: c1ccc(-n2c3ccccc3c3cc(-c4nc(-n5c6ccc(-c7cccc8c7sc7ccccc78)cc6c6c7sc8ccccc8c7ccc65)nc5ccccc45)ccc32)cc1 ; c1ccc(-c2nc(-c3ccc(-n4c5ccccc5c5cc6c(cc54)-c4ccccc4C64CCCC4)cc3)nc3ccccc23)cc1 ; c1ccc(-c2nc(-n3c4ccccc4c4cc5c(cc43)-c3ccccc3C53CCCC3)nc3ccccc23)cc1]

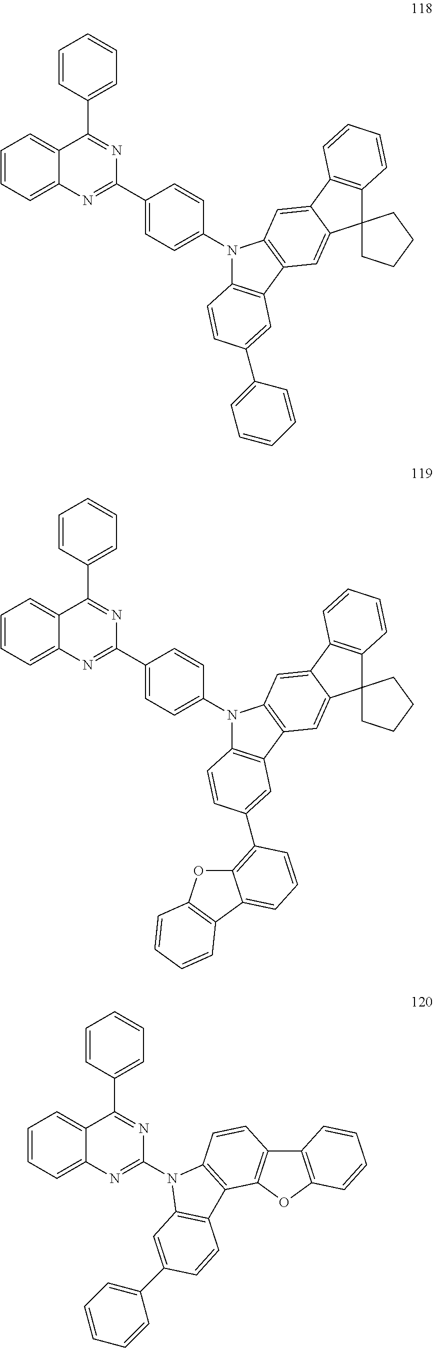 [SMILES: c1ccc(-c2ccc3c(c2)c2cc4c(cc2n3-c2ccc(-c3nc(-c5ccccc5)c5ccccc5n3)cc2)-c2ccccc2C42CCCC2)cc1 ; c1ccc(-c2nc(-c3ccc(-n4c5ccc(-c6cccc7c6oc6ccccc67)cc5c5cc6c(cc54)-c4ccccc4C64CCCC4)cc3)nc3ccccc23)cc1 ; c1ccc(-c2ccc3c4c5oc6ccccc6c5ccc4n(-c4nc(-c5ccccc5)c5ccccc5n4)c3c2)cc1]

8. An organic electroluminescent device comprising the compound for an organic electronic material of any one of claims 1 to 7.

9. The organic electroluminescent device of claim 8, which comprises a first electrode; a second electrode; and one or more organic layers interposed between the first electrode and the second electrode, wherein the organic layer comprises one or more compounds for an organic electronic material and one or more phosphorescent dopants.

10. The organic electroluminescent device of claim 9, wherein the organic layer further comprises one or more amine compounds (A) selected from the group consisting of arylamine compounds and styrylarylamine compounds; one or more metal(s) selected from the group consisting of organic metals of Group 1, Group 2, 4th period and 5th period transition metals, lanthanide metals and d-transition elements or complex compound(s) (B) comprising the metal; or a mixture thereof.

11. The organic electroluminescent device of claim 9, wherein the organic layer comprises an electroluminescent layer and a charge generating layer.

12. The organic electroluminescent device of claim 9, wherein the organic layer further comprises one or more organic electroluminescent layers emitting red, green and blue light to emit white light.
